(19) United States
(12) Patent Application Publication
(10) Pub. No.: US 2026/0313871 A1
(43) Pub. Date: Oct. 8, 2026

(54) METHOD FOR MANUFACTURING SEMICONDUCTOR MEMORY DEVICE INCLUDING A BIT LINE MASK PATTERN

(71) Applicant: Samsung Electronics Co., Ltd., Suwon-si (KR)

(72) Inventors: Kyoungmin Kim, Suwon-si (KR); Myeongsik Ryu, Suwon-si (KR); Hyuckjoon Kwon, Suwon-si (KR); Inseok Baek, Suwon-si (KR); Bok-Yeon Won, Suwon-si (KR)

(21) Appl. No.: 19/529,567

(22) Filed: Feb. 4, 2026

(30) Foreign Application Priority Data
Apr. 3, 2025 (KR) 10-2025-0043432
Jun. 25, 2025 (KR) 10-2025-0084586

(51) Int. Cl. H10B 12/00; G11C 5/06; G11C 11/4091

(52) U.S. Cl. CPC H10B 12/02; G11C 5/063; G11C 11/4091; H10B 12/482; H10B 12/50

(57) ABSTRACT

An example method for manufacturing a semiconductor memory device includes forming a PMOS region, a first NMOS region, and a second NMOS region. Forming the first NMOS region includes forming a first bit line and a second bit line extending in the first direction and spaced apart from each other in a second direction intersecting the first direction. The first mask pattern includes a first bit line mask pattern corresponding to the first bit line and a second bit line mask pattern corresponding to the second bit line, the first bit line mask pattern includes a first protrusion pattern protruding from a first end portion toward the second bit line mask pattern, and the second bit line mask pattern includes a second protrusion pattern protruding from a second end portion toward the first bit line mask pattern.

### CROSS-REFERENCE TO RELATED APPLICATION(S)

This application claims priority under 35 U.S.C. § 119 of Korean Patent Application Nos. 10-2025-0043432, filed on Apr. 3, 2025, and 10-2025-0084586, filed on Jun. 25, 2025, the entire contents of which are hereby incorporated by reference.

### BACKGROUND

The capacity and speed of semiconductor memory devices used in various electronic systems are rapidly increasing to satisfy users’ requests for high performance. In particular, a representative example of a volatile memory device may be a dynamic random access memory (DRAM). A memory cell of a DRAM stores data in the form of charge charged in a cell capacitor. A DRAM writes or reads data to/from memory cells using word lines and bit lines. Memory cells connected to a word line form a single row and operate according to voltage applied to the word line.

As the capacity of DRAMs increases, the number of memory cells connected to a single word line increases, and the distance (cell pitch) between word lines decreases. Therefore, a channel length of a transistor in a bit line sense amplifier (BLSA) region may also decrease. To overcome this limitation, various methods of patterning a gate electrode of a transistor in the bit line sense amplifier region have been used.

### SUMMARY

The present disclosure relates to a semiconductor memory device with improved integration density and reliability.

In some implementations, a method for manufacturing a semiconductor memory device includes forming, on a substrate, a PMOS region and a first NMOS region and a second NMOS region that are spaced apart from each other in a first direction with the PMOS region therebetween, where the forming of the first NMOS region includes: forming, on the substrate, a first bit line and a second bit line extending in the first direction by performing a first patterning process using a first mask pattern as a mask, where the first bit line and the second bit line are spaced apart from each other in a second direction intersecting the first direction; and forming a first source pattern between the first bit line and the second bit line, where the first mask pattern includes a first bit line mask pattern corresponding to the first bit line and a second bit line mask pattern corresponding to the second bit line, the first bit line mask pattern includes a first protrusion pattern protruding from a first end portion of the first bit line mask pattern toward the second bit line mask pattern, and the second bit line mask pattern includes a second protrusion pattern protruding from a second end portion of the second bit line mask pattern toward the first bit line mask pattern.

In some implementations, a method for manufacturing a semiconductor memory device includes forming, on a substrate, a PMOS region and a first NMOS region and a second NMOS region that are spaced apart from each other in a first direction with the PMOS region therebetween, where the forming of the PMOS region includes: forming, on the substrate, a first sensing bit line and a second sensing bit line extending in the first direction by performing a first patterning process using a first mask pattern as a mask, where the first sensing bit line and the second sensing bit line are spaced apart from each other in a second direction intersecting the first direction; and forming a drain pattern spaced apart from the second sensing bit line in the second direction with the first sensing bit line therebetween, where the first mask pattern includes a first sensing bit line mask pattern corresponding to the first sensing bit line, the first sensing bit line mask pattern includes: a first portion extending in the first direction; a second portion extending in the second direction and spaced apart from the first portion in the first direction; and a third portion between the first portion and the second portion, where the first portion, the second portion, and the third portion each include a first sidewall, a second sidewall, and a third sidewall, and the third sidewall is offset from the first sidewall and the second sidewall in the second direction.

In some implementations, a method for manufacturing a semiconductor memory device includes forming, on a substrate, a PMOS region and a first NMOS region and a second NMOS region that are spaced apart from each other in a first direction with the PMOS region therebetween, where the forming of the first NMOS region includes: forming, on the substrate, a first bit line and a second bit line extending in the first direction by performing a first patterning process using a first mask pattern as a mask, where the first bit line and the second bit line are spaced apart from each other in a second direction intersecting the first direction; forming a cancellation region adjacent to the PMOS region, where the cancellation region includes a cancellation gate electrode extending in the second direction; forming a first interlayer insulating layer on the first and second bit lines; forming a first source pattern between the first bit line and the second bit line; forming first drain patterns between the first bit line and the cancellation gate electrode and between the second bit line and the cancellation gate electrode; and forming a wiring layer on the first interlayer insulating layer, where the first mask pattern includes a first bit line mask pattern corresponding to the first bit line and a second bit line mask pattern corresponding to the second bit line, the first bit line mask pattern includes a first protrusion pattern protruding from a first end portion of the first bit line mask pattern toward the second bit line mask pattern, and the second bit line mask pattern includes a second protrusion pattern protruding from a second end portion of the second bit line mask pattern toward the first bit line mask pattern.

### BRIEF DESCRIPTION OF THE DRAWINGS

The accompanying drawings are included to provide a further understanding of the present disclosure, and are incorporated in and constitute a part of this specification. The drawings illustrate some implementations of the present disclosure and, together with the description, serve to explain principles of the present disclosure.

FIG. 1 is a plan view schematically illustrating an example of a semiconductor memory chip to describe a semiconductor memory device.

FIG. 2A is a diagram illustrating an example of an electronic device.

FIG. 2B is a diagram for describing an example of a sensing operation of the bit line sense amplifier BLSA.

FIG. 2C is a block diagram illustrating an example of a bit line sense amplifier.

FIG. 2D is a circuit diagram illustrating an example of a bit line sense amplifier.

FIG. 2E is a circuit diagram illustrating an example of an operation of the bit line sense amplifier BLSA.

FIG. 3 is a plan view of an example of a bit line sense amplifier.

FIG. 4A is an example plan view according to the first NMOS region NSA1 of FIG. 3.

FIG. 4B is an example plan view according to the second NMOS region NSA2 of FIG. 3.

FIG. 5A is an example cross-sectional view taken along line A-A’ of FIG. 4A.

FIG. 5B is an example cross-sectional view taken along line B-B’ of FIG. 4B.

FIG. 6 is an example plan view according to the PMOS region PSA of FIG. 3.

FIG. 7A is an example cross-sectional view taken along line C-C’ of FIG. 6.

FIG. 7B is an example cross-sectional view taken along line D-D’ of FIG. 6.

FIG. 8A is an example plan view of the first NMOS region NSA1 of FIG. 3.

FIG. 8B is an example plan view of the PMOS regions PSA of FIG. 3.

FIGS. 9, 10A, 10B, 11, 12, 13, 14A, 14B, 15, 16, 19, 20A, 20B, 21, 22A and 22B are diagrams for describing an example of a method for manufacturing a semiconductor memory device.

FIG. 17 is a plan view according to the first NMOS region NSA1 of FIG. 3 for describing an example of a method for manufacturing a semiconductor memory device.

FIG. 18 is a plan view according to the PMOS region PSA of FIG. 3 for describing an example of a method for manufacturing a semiconductor memory device.

### DETAILED DESCRIPTION

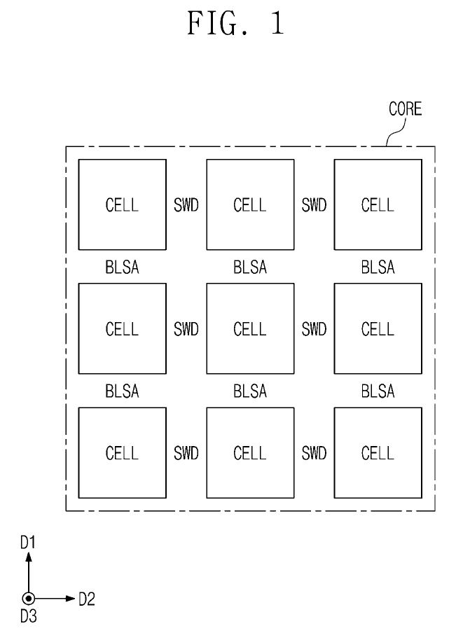

FIG. 1 is a plan view schematically illustrating an example of a semiconductor memory chip to describe a semiconductor memory device.

Referring to FIG. 1, a substrate 100 including a cell region CELL and a core/peri region CORE may be provided. In the cell region CELL, memory cells for storing data may be arranged in an array form. For example, the cell region CELL may include DRAM cells.

The core/peri region CORE may be disposed around the cell region CELL or in a separate region different from the cell region CELL. Control elements and dummy elements may be formed on the core/peri region CORE. In other words, circuits required for controlling memory cells of the cell region CELL may be provided on the core/peri region CORE.

A plurality of sub word line divers SWD may be arranged on the core/peri region CORE. The sub word line driver SWD may enable a word line connected to a gate of a memory cell transistor. In other words, the sub word line driver SWD may operate a word line.

A plurality of bit line sense amplifiers BLSA may be arranged on the core/peri region CORE. The bit line sense amplifier may enable a bit line of a memory cell transistor. The bit line sense amplifier may amplify a potential difference between a bit line and a bit line bar (complementary bit line).

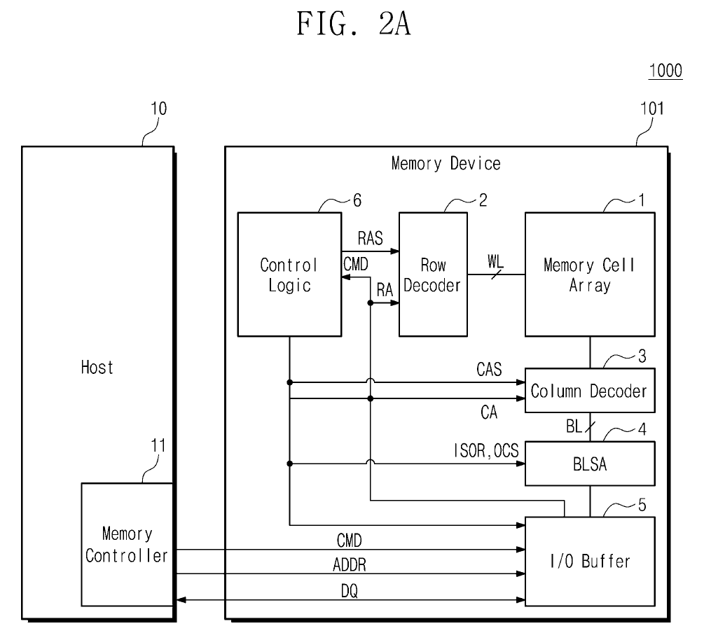

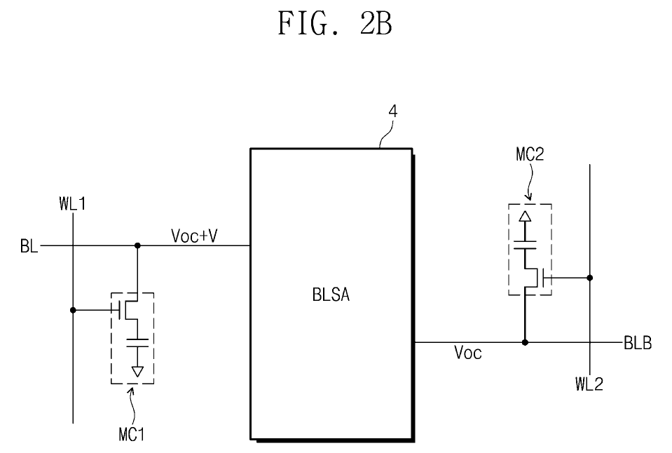

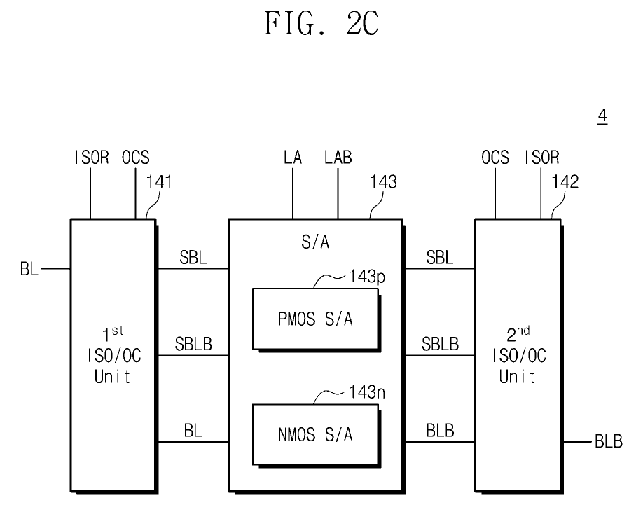

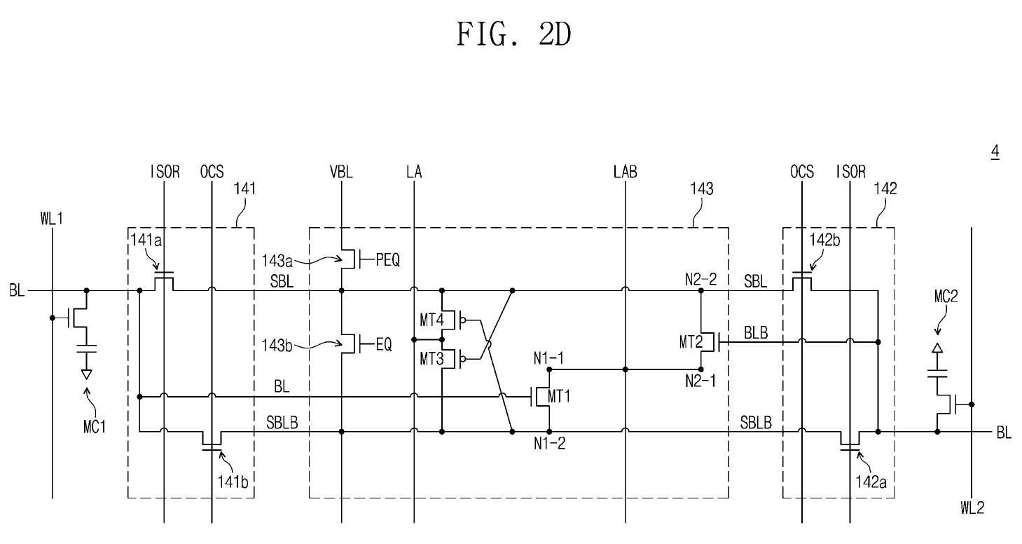

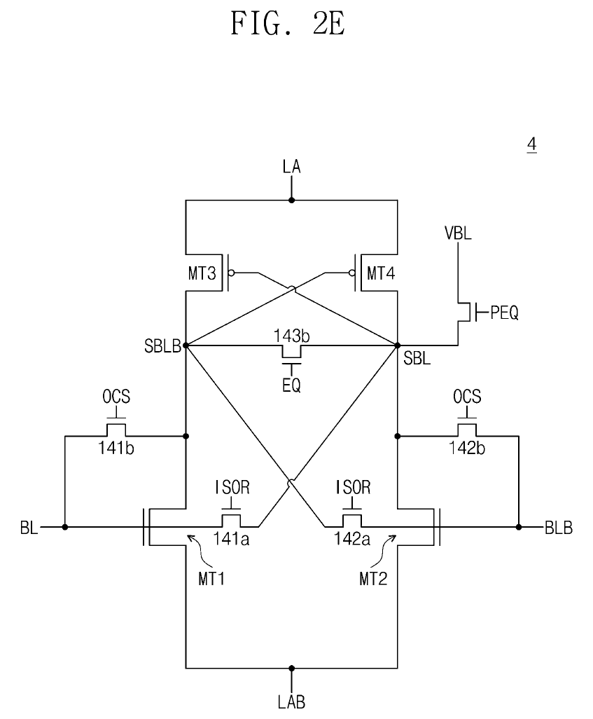

FIG. 2A is a diagram illustrating an example of an electronic device. FIG. 2B is a diagram for describing an example of a sensing operation of the bit line sense amplifier BLSA. FIG. 2C is a block diagram illustrating an example of a bit line sense amplifier. FIG. 2D is a circuit diagram illustrating an example of a bit line sense amplifier. FIG. 2E is a circuit diagram illustrating an example of an operation of the bit line sense amplifier BLSA.

The bit line sense amplifier operates based on precharge, offset cancellation, charge sharing, pre-sensing, and restoring operations.

The bit line sense amplifier includes various semiconductor devices. The semiconductor devices included in the bit line sense amplifier may differ from each other in terms of characteristics (e.g., threshold voltage) due to a process variation, temperature (PVT), etc. Accordingly, offset noise of the bit line sense amplifier may occur. Therefore, the bit line sense amplifier may perform an offset cancellation operation between a precharge operation and a charge sharing operation.

However, it is assumed hereinafter that the offset noise does not occur in the bit line sense amplifier. In this case, the offset cancellation operation may represent that voltage levels of a bit line BL and a complementary bit line BLB reduce by as much as a threshold voltage of the semiconductor devices included in the bit line sense amplifier. Relevant detailed descriptions will be provided later.

FIG. 2A is a diagram illustrating an electronic device 1000. Referring to FIG. 2A, the electronic device 1000 may include a host 10, a memory controller 11, and a memory device 101.

The host 10 including the memory controller 11 may transmit a command and address CMD and ADDR to the memory device 101. Alternatively, the host 10 may transmit the command and address CMD and ADDR to the memory device 101 via the memory controller 11. The host 10 including the memory controller 11 may exchange a data signal DQ with the memory device 101.

Hereinafter, it is assumed that the host 10 including the memory controller 11 transmits the command and address CMD and ADDR to the memory device 101.

For example, the host 10 may transmit a write command, an address, and the data signal DQ to the memory device 101. The memory device 101 may write data to memory cells corresponding to the command and address received from the host 10.

For example, the host 10 may transmit a read command and an address to the memory device 101. The memory device 101 may transmit data read from memory cells corresponding to the command address received from the host 10 to the host 10 as the data signal DQ.

The memory device 101 may be a dynamic random access memory (DRAM), but is not limited thereto. The memory device 101 may be one of various random access memories such as a static random access memory (SRAM), a magnetic random access memory (MRAM), a phase change random access memory (PRAM), a ferroelectric random access memory (FRAM), and a resistive random access memory (RRAM).

The memory device 101 may include a memory cell array 1, a row decoder 2, a column decoder 3, a bit line sense amplifier (BLSA) 4, an input/output buffer 5, and a control logic 6.

The memory cell array 1 may include a plurality of memory cells arranged in row and column directions. Each of the plurality of memory cells may be connected to one of a plurality of word lines WL and one of a plurality of bit lines BL.

The row decoder 2 may select any one of the plurality of word lines WL connected to the memory cell array 1. For example, the row decoder 2 may receive a row address RA from the input/output buffer 5. The row decoder 2 may select any one word line corresponding to the received row address RA from among the plurality of word lines WL. The row decoder 2 may activate a selected word line in response to a row address control signal RAS. The row address control signal RAS may be received from the host 10.

The column decoder 3 may select any one of the plurality of bit lines BL connected to the memory cell array 1. For example, the column decoder 3 may receive a column address CA from the input/output buffer 5. The column decoder 3 may select any one bit line corresponding to the received column address CA from among the plurality of bit lines BL. The column decoder 3 may activate a selected bit line in response to a column address control signal CAS. The column address control signal CAS may be received from the host 10.

The BLSA 4 may be connected to the plurality of bit lines BL connected to the memory cell array 1. The BLSA 4 may sense a voltage change of an activated bit line among the plurality of bit lines BL, and may amplify and output the voltage change. A configuration and operations of the BLSA 4 will be described in more detail with reference to the accompanying drawings.

The input/output buffer 5 may receive the address ADDR from the host 10. The input/output buffer 5 may transmit the row address RA to the row decoder 2. The input/output buffer 5 may transmit the column address CA to the column decoder 3. The input/output buffer 5 may receive the command CMD from the host 10 and transmit the command CMD to the control logic 6. The input/output buffer 5 may output data to the host 10 as the data signal DQ based on a voltage amplified by the BLSA 4.

The control logic 6 may control overall components of the memory device 101. The control logic 6 may control the row decoder 2 based on the row address control signal RAS. The control logic 6 may control the column decoder 3 based on the column address control signal CAS. The control logic 6 may control the input/output buffer 5 based on a control signal.

The control logic 6 may control the BLSA 4 based on an isolation signal ISOR and an offset cancellation signal OCS. The BLSA 4 may perform the offset cancellation operation and the pre-sensing operation according to the received isolation signal ISOR and offset cancellation signal OCS. Relevant detailed descriptions will be provided later.

FIG. 2B is a diagram for describing the sensing operation of the BLSA 4. For conciseness, components other than the BLSA 4, the bit line BL, the complementary bit line BLB, first and second word lines WL1 and WL2, and first and second memory cells MC1 and MC2 are omitted.

Referring to FIG. 2B, the BLSA 4 may be electrically connected to bit lines of the memory device 101, and may sense and amplify data stored in the plurality of memory cells of the memory device 101 based on a voltage difference between two complementary bit lines among the bit lines during a read operation or refresh operation of the memory device 101.

The BLSA 4 may be connected to the bit line BL and the complementary bit line BLB that are complementary to each other.

The first memory cell MC1 may be connected to the bit line BL, and the second bit line MC2 may be connected to the complementary bit line BLB. The first memory cell MC1 may be connected to the first word line WL1, and the second memory cell MC2 may be connected to the second word line WL2. The first and second memory cells MC1 and MC2 may each include a cell transistor and a cell capacitor.

In this case, the first memory cell MC1 connected to the bit line BL may be selected by voltages applied to the word lines WL1 and WL2, and the second memory cell MC2 connected to the complementary bit line BLB may not be selected.

Before the first word line WL1 connected to the first memory cell MC1 is activated, the bit line BL connected to the first memory cell MC1 may be in a state of being charged or discharged to a voltage level Voc after the precharge operation and the offset cancellation operation.

Thereafter, since the first word line WL1 is activated, charge sharing between charge of the first bit line BL1 charged to the voltage level Voc and charge of the capacitor of the first memory cell MC1 may occur. For example, in FIG. 2B, when a logical value of data stored in the first memory cell MC1 is “1”, a voltage level of the first bit line BL may increase by as much as a voltage variation V due to the charge sharing.

Although not illustrated, when the logical value of data stored in the first memory cell MC1 is “0”, the voltage level of the first bit line BL may decrease by as much as the voltage variation V due to the charge sharing.

A voltage level of the complementary bit line BLB connected to the second word line WL2 not activated may maintain the voltage level Voc after the precharge operation and the offset cancellation operation.

Although FIG. 2B illustrates that only one memory cell (e.g., the first memory cell MC1, the second memory cell MC2) is connected to each of the bit line BL and the complementary bit line BLB, this is an example, and multiple memory cells may be connected to each of the bit line BL and the complementary bit line BLB.

FIG. 2C is a block diagram illustrating the BLSA 4. For conciseness, unnecessary components for describing a configuration and operation of the BLSA 4 are omitted. However, the scope of the present disclosure is not limited thereto, and components such as a conjunction circuit (CJT) may be further included. Relevant detailed descriptions will be provided later.

Referring to FIG. 2C, the BLSA 4 may include a first isolation/offset cancellation (ISO/OC) unit 141, a second isolation/offset cancellation unit 142, and a sense amplifier circuit 143.

The first isolation/offset cancellation unit 141 is connected to the bit line BL, a sensing bit lines SBL, and a complementary sensing bit line SBLB. The second isolation/offset cancellation unit 142 is connected to the complementary bit line BLB, the sensing bit line SBL, and the complementary sensing bit line SBLB. The first and second isolation/offset cancellation units 141 and 142 may receive an isolation signal ISOR and an offset cancellation signal OCS and may operate based on the received isolation signal ISOR and offset cancellation signal OCS.

For example, the first isolation/offset cancellation unit 141 may disconnect the bit line BL and the sensing bit line SBL in response to the isolation signal ISOR. The first isolation/offset cancellation unit 141 may disconnect the bit line BL and the complementary sensing bit line SBLB in response to the offset cancellation signal OCS. The second isolation/offset cancellation unit 142 may disconnect the complementary bit line BLB and the complementary sensing bit line SBLB in response to the isolation signal ISOR. The second isolation/offset cancellation unit 142 may disconnect the complementary bit line BLB and the sensing bit line SBL in response to the offset cancellation signal OCS.

The sense amplifier circuit 143 includes a PMOS sense amplifier circuit 143p and an NMOS sense amplifier circuit 143n. The sense amplifier circuit 143 may sense and amplify a voltage difference between the bit line BL and the complementary bit line BLB according to first and second supply signals LA and LAB. For example, the NMOS sense amplifier circuit 143nis directly connected to the bit line BL and the complementary bit line BLB. Gates of transistors included in the NMOS sense amplifier circuit 143n are respectively connected to the bit line BL and the complementary bit line BLB.

FIG. 2D is a circuit diagram illustrating a bit line sense amplifier in detail. Referring to FIG. 2D, the BLSA 4 includes the first isolation/offset cancellation unit 141, the second isolation/offset cancellation unit 142, and the sense amplifier circuit 143.

The first isolation/offset cancellation unit 141 may include a first isolation switch 141a and a first offset cancellation switch 141b. One end of the first isolation switch 141a may be connected to the bit line BL, and the other end may be connected to the sensing bit line SBL through a node N2-2. The first isolation switch 141a operates according to the isolation signal ISOR applied to a gate terminal.

One end of the first offset cancellation switch 141b may be connected to the bit line BL, and the other end may be connected to the complementary sensing bit line SBLB through a node N1-2. The first offset cancellation switch 141bmay operate according to the offset cancellation signal OCS applied to a gate terminal.

The second isolation/offset cancellation unit 142 may include a second isolation switch 142a and a second offset cancellation switch 142b. One end of the second isolation switch 142a may be connected to the complementary bit line BLB, and the other end may be connected to the complementary sensing bit line SBLB. The second isolation switch 142a may operate according to the isolation signal ISOR applied to a gate terminal.

One end of the second offset cancellation switch 142b may be connected to the complementary bit line BLB, and the other end may be connected to the sensing bit line SBL. The second offset cancellation switch 142bmay operate according to the offset cancellation signal OCS applied to a gate terminal.

The sense amplifier circuit 143 may include first and second PMOS transistors MT3 and MT4 and first and second NMOS transistors MT1 and MT2. For example, the PMOS sense amplifier circuit 143p (see FIG. 2C) may include the first and second PMOS transistors MT3 and MT4. The NMOS sense amplifier circuit 143n (see FIG. 2C) may include the first and second NMOS transistors MT1 and MT4.

One end of the first PMOS transistor MT3 may be connected to the complementary sensing bit line SBLB through the node N1-2, the other end may be connected to a first power supply node to which a first power supply signal LA is applied, and a gate may be connected to the sensing bit line SBL through the node N2-2.

One end of the second PMOS transistor MT4 may be connected to the sensing bit line SBL through the node N2-2, the other end may be connected to the first power supply node to which the first power supply signal LA is applied, and a gate may be connected to the complementary sensing bit line SBLB through the node N1-2.

One end of the first NMOS transistor MT1 may be connected to the node N1-2 corresponding to the complementary sensing bit line SBLB, the other end may be connected to a second power supply node to which the second supply signal LAB is applied through the node N1-1, and a gate may be connected to the bit line BL.

One end of the second NMOS transistor MT2 may be connected to the node N2-2 corresponding to the sensing bit line SBL, the other end may be connected to the second power supply node to which the second supply signal LAB is applied through the node N2-1, and a gate may be connected to the complementary bit line BLB.

The bit line BL may be connected to one end of a driving switch included in the first memory cell MC1. The first word line WL1 may be connected to a gate of the driving switch included in the first memory cell MC1

The sense amplifier circuit 143 may further include a first equalization switch 143a and a second equalization switch 143b. The first equalization switch 143a may operate independent of the second equalization switch 143b.

The first equalization switch 143a may have a gate terminal for receiving a first equalization signal PEQ and may be connected between the node N2-2 and a third power supply node to which a third power supply signal VBL is applied, and the second equalization switch 143b may have a gate terminal for receiving a second equalization signal EQ and may be connected between the node N1-2 and the node N2-2.

FIG. 2E is a circuit diagram illustrating operations of the BLSA 4. The BLSA 4 illustrated in FIG. 2E may be an equivalent circuit of the BLSA 4 of FIG. 2D.

Components having the same reference signs in FIGS. 2D and 2E may perform substantially the same functions. The BLSA 4 may include the first and second isolation switches 141a and 142a, the first and second offset cancellation switches 141b and 142b, the first and second PMOS transistors MT3 and MT4, the first and second NMOS transistors MT1 and MT2, and the first and second equalization switches 143a and 143b.

The sensing bit line SBL and the complementary sensing bit line SBLB of FIG. 2D may be expressed as nodes in FIG. 2E. A node corresponding to the sensing bit line SBL of FIG. 2D may be referred to as a “first internal node”, and a node corresponding to the complementary sensing bit line SBLB of FIG. 2D may be referred to as a “second internal node”.

The second PMOS transistor MT4 may be connected between the first power supply node to which the first power supply signal LA is applied and the first internal node, and the first PMOS transistor MT3 may be connected between the first power supply node and the second internal node.

The first internal node may be connected to a drain terminal of the second NMOS transistor MT2, and the second internal node may be connected to a drain terminal of the first NMOS transistor MT1. Gate terminals of the first PMOS transistor MT3 and the second PMOS transistor MT4 may be cross connected to the first internal node and the second internal node.

Hereinafter, operations of the BLSA 4 will be described. In FIG. 2E, the BLSA 4 may perform a precharge operation, an offset cancellation operation, and a charge sharing operation.

The BLSA 4 may perform the precharge operation.

The first and second offset cancellation switches 141b and 142b, and the first and second isolation switches 141a and 142a may be turned on according to the first and second equalization signals PEQ and EQ, the offset cancellation signal OCS, and the isolation signal ISOR.

A voltage level of each of the first and second power supply signals LA and LAB may have a first driving voltage that is one of driving voltages of the memory device 101.

Each of voltage levels of the sensing bit line SBL and the complementary sensing bit line SBLB may have the first driving voltage. Since the first and second isolation switches 141aand 142a are turned on and the first and second offset cancellation switches 141b and 142b are turned on, the sensing bit line SBL may be short-circuited with the bit line BL, and the complementary sensing bit line SBLB may be short-circuited with the complementary bit line BLB. Therefore, the bit line and complementary bit line BL and BLB may be precharged with the first driving voltage.

The BLSA 4 may perform the offset cancellation operation.

The first and second equalization signals PEQ and EQ and the isolation signal ISOR may each be maintained at a low level or transition to a low level. The offset cancellation signal OCS may be maintained at a high level. In this case, the first and second equalization switches 143a and 143b and the first and second isolation switches 141a and 142a may be turned off, and the first and second offset cancellation switches 141b and 142b may be turned on.

A voltage level of the first power supply signal LA may transition to a first voltage level (e.g., VINTA) different from the first driving voltage, and a second voltage level of the second power supply signal LAB may transition to a voltage level (e.g., VSS) different from the first driving voltage. When performing the offset cancellation operation, the first voltage level VINTA may correspond to an input voltage, and the second voltage VSS may correspond to a ground voltage.

A voltage level of each of the sensing bit line and the complementary sensing bit line SBL and SBLB may be determined to be between the first voltage level VINTA and the second voltage level VSS. A voltage level of each of the sensing bit line and complementary sensing bit line SBL and SBLB may be determined based on mismatch components of the first and second NMOS transistors MT1 and MT2.

Since the first and second offset cancellation switches 141b and 142b are turned on, the sensing bit line SBL may be short-circuited with the complementary bit line BLB, and the complementary sensing bit line SBLB may be short-circuited with the bit line BL.

When there are no mismatch components of the first and second NMOS transistors MT1 and MT2, it is not necessary to compensate offset. However, in this case, voltage levels of the bit line and complementary bit line BL and BLB may reduce from the first driving voltage by as much as a threshold voltage of the first and second NMOS transistors MT1 and MT2.

The BLSA 4 may perform the charge sharing operation.

The second equalization signal EQ may transition to a high level or may be maintained at a high level. The first equalization signal PEQ, the offset cancellation signal OCS, and the isolation signal ISOR may each be maintained at a low level or transition to a low level. In this case, the second equalization switch 143b may be turned on. The first equalization switch 143a, the first and second offset cancellation switches 141b and 142b, and the first and second isolation switches 141a and 142a may be turned off.

A voltage level of the first power supply signal LA may transition from the first voltage level VINTA to the first driving voltage. A voltage level of the second power supply signal LAB may transition from the second voltage level VSS to the first driving voltage.

Since the first equalization switch 143a is turned off, the sensing bit line and complementary sensing bit line SBL and SBLB may not have a voltage level of the first driving voltage. Since the voltage level of the first power supply signal LA transitions to the first driving voltage earlier than the voltage level of the second power supply signal LAB, the voltage levels of the sensing bit line and complementary sensing bit line SBL and SBLB may transition from a voltage level obtained after the offset cancellation operation by as much as a predetermined level.

Since the second equalization switch 143b is turned on, the sensing bit line and complementary sensing bit line SBL and SBLB may have the same voltage level.

The voltage level of the bit line BL may be determined based on a result of charge sharing between the first memory cell MC1 and the bit line BL connected to the first memory cell MC1.

In this case, a predetermined voltage may be applied to the first word line WL1 connected to the first memory cell MC1 so that a cell capacitor of the first memory cell MC1 may be connected to the bit line BL. Since the complementary bit line BLB is complementary to the bit line BL, charge sharing may not be performed on data stored in the second memory cell MC2.

For example, when data representing a logical value “1” is stored (i.e., cell data is “1”) in the first memory cell MC1, the voltage level of the bit line BL may increase by as much as a predetermined level (e.g., V of FIG. 2B) compared to a voltage level (e.g., Voc of FIG. 2B) obtained immediately after the offset cancellation operation is performed.

Although not illustrated, when data representing a logical value “0” is stored (i.e., cell data is “0”) in the first memory cell MC1, the voltage level of the bit line BL may decrease by as much as a predetermined level compared to a voltage level (e.g., Voc of FIG. 2B) obtained immediately after the offset cancellation operation is performed.

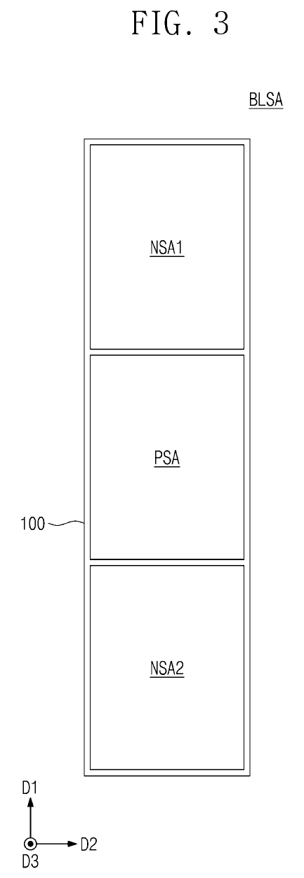

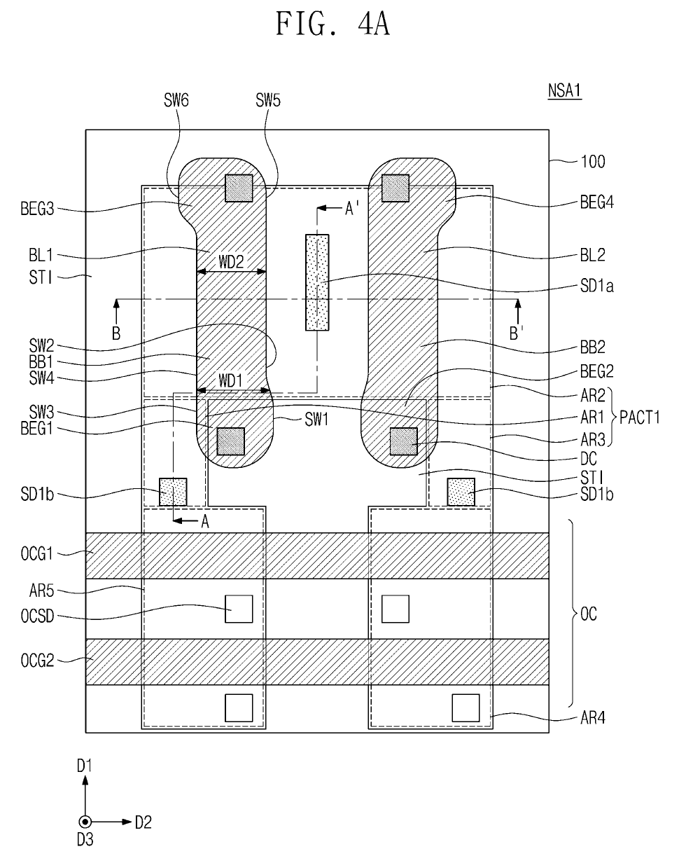

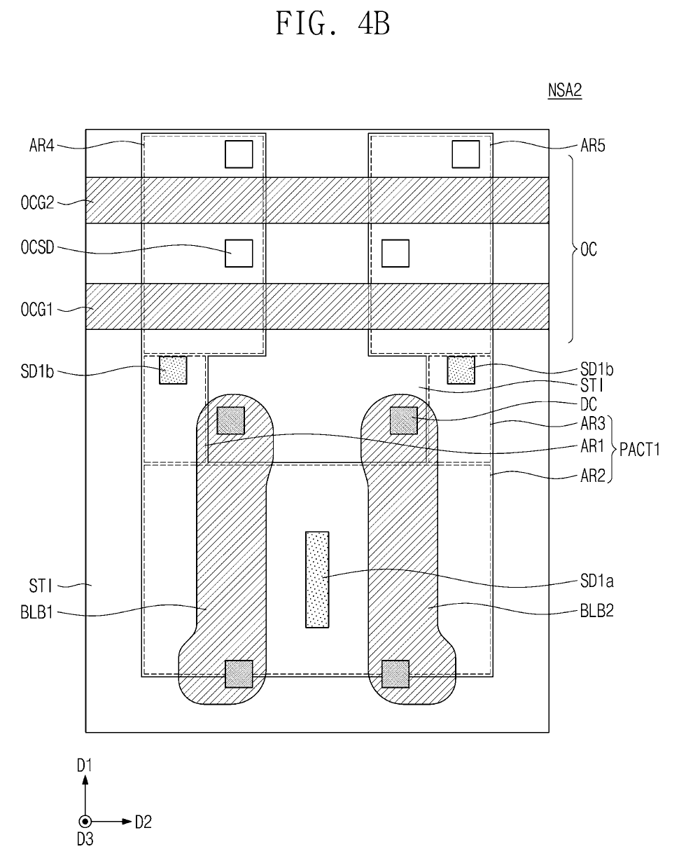

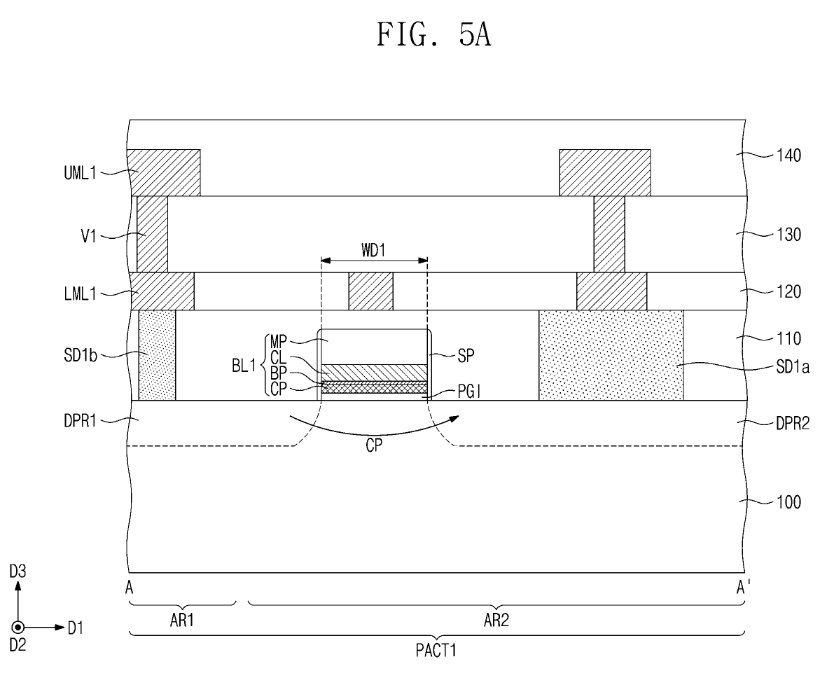

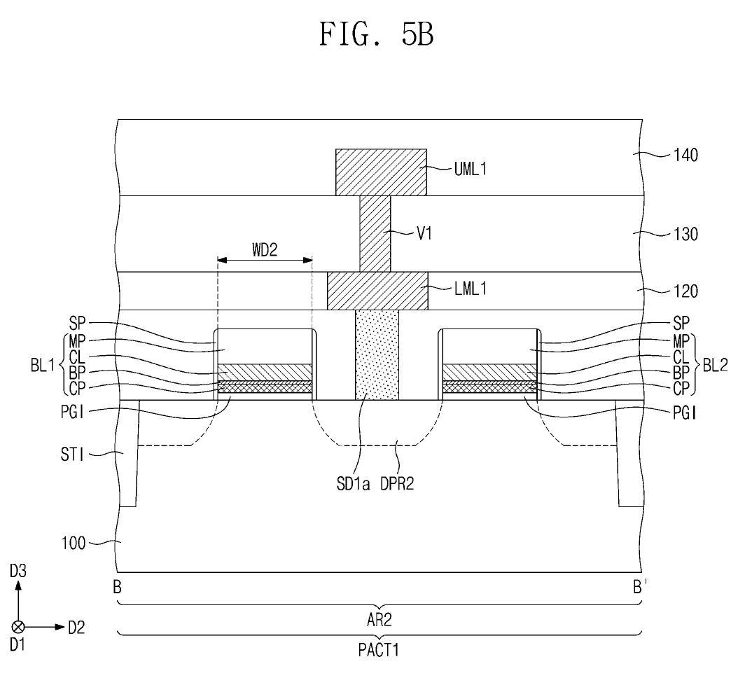

FIG. 3 is a plan view of an example of a bit line sense amplifier. FIG. 4A is an example plan view according to the first NMOS region NSA1 of FIG. 3. FIG. 4B is an example plan view according to the second NMOS region NSA2 of FIG. 3. FIG. 5A is an example cross-sectional view taken along line A-A’ of FIG. 4A. FIG. 5B is an example cross-sectional view taken along line B-B’ of FIG. 4B. The NMOS regions NSA1 and NSA2 will be described in more detail with reference to FIGS. 3 to 5B.

Referring to FIG. 3, a substrate 100 may be a semiconductor substrate including silicon, germanium, or silicon-germanium. A PMOS region PSA and the NMOS regions NSA1 and NSA2 may be included on the substrate 100. The NMOS regions NSA1 and NSA2 may include the first NMOS region NSA1 and the second NMOS region NSA2. The NMOS regions NSA1 and NSA2 may include an n-type transistor and may pull down a bit line in a direction of ground voltage GND. On the contrary, the PMOS region PSA may include a p-type transistor and may pull up a bit line in a direction of drain voltage Vdd.

The first NMOS region NSA1 and the second NMOS region NSA2 may be spaced apart from each other in a first direction D1 with the PMOS region PSA therebetween. The bit lines BL may extend in the first direction D1 on the PMOS region PSA and the NMOS regions NSA1 and NSA2.

Referring to FIGS. 4A, 5A and 5B, a device isolation layer STI defining a first peripheral active region PACT1 may be provided on the substrate 100. In a plan view, the device isolation layer STI may surround the first peripheral active region PACT1. In a plan view, the device isolation layer STI may extend between portions of the first peripheral active region PACT1 so as to have a T shape, but is not limited thereto. The device isolation layer STI may include a silicon oxide layer.

The first peripheral active region PACT1 may include first to fifth regions AR1 to AR5. The first to fifth regions AR1 to AR5 may be sequentially and clockwise arranged around the device isolation layer STI. In other words, the first to fifth regions AR1 to AR5 may surround the device isolation layer STI.

The second region AR2 may be spaced apart from the fourth region AR4 and the fifth region AR5 in the first direction D1. The first region AR1 may connect the second region AR2 and the fifth region AR5, and the third region AR3 may connect the second region AR2 and the fourth region AR4. The device isolation layer STI may be provided between the first region AR1 and the third region AR3 and between the fourth region AR4 and the fifth region AR5. A width of the second region AR2 in a second direction D2 may be larger than a width of the fourth region AR4 and a width of the fifth region AR5. A width of the first region AR1 and a width of the third region AR3 may be less than the width of the fourth region AR4 and the width of the fifth region AR5.

The first to fourth regions AR1 to AR3 may constitute an NMOS transistor. A first drain pattern SD1b may be provided on each of the first and third regions AR1 and AR3, and a first source pattern SD1a may be provided on the second region AR2. The first source pattern SD1a may extend in the first direction D1. A length of the first source pattern SD1a in the first direction D1 may be larger than a length of the first drain pattern SD1b in the first direction D1.

The first drain pattern SD1b may be arranged adjacent to a cancellation region OC that will be described later. For example, the first drain pattern SD1b may be provided between a first bit line BL1 that will be described later and a first cancellation gate electrode OCG1 that will be described later and between a second bit line BL2 that will be described later and the first cancellation gate electrode OCG1.

The first drain pattern SD1b may be connected to a first impurity region DPR1 of the first region AR1. The first source pattern SD1a may be connected to a second impurity region DPR2 of the second region AR2. The first and second impurity regions DPR1 and DPR2 may be n-type doped regions. A current path may be formed from the first impurity region DPR1 to the second impurity region DPR2. In other words, a channel region may be formed from the first impurity region DPR1 to the second impurity region DPR2.

The first bit line BL1 and the second bit line BL2 may be provided on the first to third regions AR1 to AR3. The first and second bit lines BL1 and BL2 may extend in the first direction D1 on the device isolation layer STI and the first to third regions AR1 to AR3. The first bit line BL1 and the second bit line BL2 may be spaced apart from each other in the second direction D2. The first source pattern SD1a may be located between the first bit line BL1 and the second bit line BL2.

The first bit line BL1 may include a first bit line end portion BEG1 and a third bit line end portion BEG3 facing each other in the first direction D1. The first bit line end portion BEG1 may vertically overlap the first region AR1, the second region AR2, and the device isolation layer STI. The first bit line BL1 may include a first bit line body portion BB1 between the first bit line end portion BEG1 and the third bit line end portion BEG3.

The first bit line end portion BEG1 may have a first width WD1 in the second direction D2. The first bit line body portion BB1 may have a second width WD2 in the second direction D2. The first width WD1 may be larger than the second width WD2. The first bit line end portion BEG1 may further protrude toward the second bit line BL2 than the first bit line body portion BB1. In other words, the first bit line end portion BEG1 may extend further toward the second bit line BL2 than the first bit line body portion BB1.

One sidewall SW1 of the first bit line end portion BEG1 may protrude above one sidewall SW2 of the first bit line body portion BB1 in the second direction D2. On the contrary, another sidewall SW3 of the first bit line end portion BEG1 may be aligned with another sidewall SW4 of the first bit line body portion BB2 in the first direction D1, but is not limited thereto. The one sidewall SW1 and the other sidewall SW3 of the first bit line end portion BEG1 may face each other in the second direction D2, and the one sidewall SW2 and the other sidewall SW4 of the first bit line body portion BB1 may also face each other in the second direction D2.

A width of the third bit line end portion BEG3 in the second direction D2 may be larger than the second width WD2. The third bit line end portion BEG3 may further protrude in a direction away from the second bit line BL2 than the first bit line body portion BB1. In other words, the third bit line end portion BEG3 may protrude and extend in an opposite direction to the first bit line end portion BEG1.

One sidewall SW5 of the third bit line end portion BEG3 may be aligned with the one sidewall SW2 of the first bit line body portion BB1 in the first direction D1. On the contrary, another sidewall SW6 of the third bit line end portion BEG3 may protrude above the other sidewall SW4 of the first bit line body portion BB1 in a direction away from the second bit line BL2. The one sidewall SW5 and the other sidewall SW6 of the third bit line end portion BEG3 may face each other in the second direction D2.

The second bit line BL2 may have substantially the same feature as the first bit line BL1. In detail, the second bit line BL2 may include a second bit line end portion BEG2 and a fourth bit line end portion BEG4 facing each other in the first direction D1. The second bit line end portion BEG2 may correspond to the first bit line end portion BEG1, and the fourth bit line end portion BEG4 may correspond to the third bit line end portion BEG3. The second bit line BL2 may include a second bit line body portion BB2 between the second bit line end portion BEG2 and the fourth bit line end portion BEG4. The second bit line body portion BB2 may correspond to the first bit line body portion BB1. In a plan view, the first bit line end portion BEG1 and the second bit line end portion BEG2 may have a round profile.

The second bit line BL2 may have a profile that is symmetric with the first bit line BL1 in the second direction D2. The second bit line end portion BEG2 may extend toward the first bit line BL1, and the fourth bit line end portion BEG4 may extend in a direction away from the first bit line BL1. Therefore, a distance between the first bit line end portion BEG1 and the second bit line end portion BEG2 may be less than a distance between the first bit line body portion BB1 and the second bit line body portion BB2.

Lower contacts DC may be respectively formed on the first to fourth bit line end portions BEG1 to BEG4. The lower contacts DC may connect the first and second bit lines BL1 and BL2 to lower lines LML1 that will be described later.

The first NMOS region NSA1 may include the cancellation region OC adjacent to the PMOS region PSA. The fourth and fifth regions AR4 and AR5 may be located on the cancellation region OC. The cancellation region OC may constitute an offset cancellation transistor. The cancellation region OC may remove and/or cancel an offset between voltages or bit lines.

The cancellation gate electrodes OCG1 and OCG2 may be provided on the cancellation region OC. The cancellation gate electrodes OCG1 and OCG2 may extend in the second direction D2 on the device isolation layer STI and the fourth and fifth regions AR4 and AR5. The cancellation gate electrodes OCG1 and OCG2 may include a first cancellation gate electrode OCG1 and a second cancellation gate electrode OCG2 spaced apart from each other in the first direction D1.

A cancellation source pattern OCSD may be provided on the fourth and fifth regions AR4 and AR5, but is not limited thereto. A drain pattern may not be provided on the fourth and fifth regions AR4 and AR5. This is because the cancellation gate electrodes OCG1 and OCG2 may share the first drain patterns SD1b on the first and third regions AR1 and AR3 with the first and second bit lines BL1 and BL2 that will be described later.

Referring to FIG. 4B, the second NMOS region NSA2 may be substantially the same as the first NMOS region NSA1. However, the second NMOS region NSA2 may be symmetric with the first NMOS region NSA1 with respect to the first direction D1. Furthermore, the second NMOS region NSA2 may include first and second complementary bit lines BLB1 and BLB2 respectively corresponding to the first and second bit lines BL1 and BL2 of the first NMOS region NSA1. The first complementary bit line BLB1 may correspond to and be paired with the first bit line BL1, and the second complementary bit line BLB2 may correspond to and be paired with the second bit line BL2.

The first and second bit lines BL1 and BL2 may include a first conductive pattern CP, a barrier pattern BP, a second conductive pattern CL, and an etching pattern MP that are sequentially stacked. A peripheral gate insulating layer PGI may be provided between the first and second bit lines BL1 and BL2 and the substrate 100. In other words, the peripheral gate insulating layer PGI may be interposed between the first conductive pattern CP and the substrate 100. A pair of spacers SP may be provided on both sidewalls of the first and second bit lines BL1 and BL2.

For example, the first conductive pattern CP may include a doped semiconductor material (doped silicon, doped germanium, and the like). The barrier pattern BP may include conductive metal nitride (e.g., titanium nitride or tantalum nitride). The second conductive pattern CL may include a metal material (e.g., titanium, tantalum, tungsten, copper, or aluminum). The peripheral gate insulating layer PGI may include a first insulating layer (e.g., silicon oxide layer) and a second insulating layer (e.g., silicon oxynitride layer), which are sequentially stacked. The spacers SP may include a silicon oxide layer, a silicon nitride layer, and/or a silicon oxynitride layer.

The first and second complementary bit lines BLB1 and BLB2 may include substantially the same components as the first and second bit lines BL1 and BL2. In detail, the first and second complementary bit lines BLB1 and BLB2 may also include a first conductive pattern CP, a barrier pattern BP, a second conductive pattern CL, and an etching pattern MP that are sequentially stacked.

According to the present disclosure, the first and second bit line end portions BEG1 and BEG2 of the first and second bit lines BL1 and BL2 may have larger widths than those of the first and second bit line body portions BB1 and BB2. Therefore, since the widths of the bit lines BL1 and BL2 between the first drain pattern SD1b and the first source pattern SD1a increase, a channel length may increase.

Furthermore, the first and second bit lines BL1 and BL2 and the first and second complementary bit lines BLB1 and BLB2 have the same profiles symmetric with each other, a mismatch between the first bit line BL1 and the first complementary bit line BLB1 and between the second bit line BL2 and the second complementary bit line BLB2 may be minimized. As a result, reliability and electrical characteristics of the semiconductor memory device of the present disclosure may be improved.

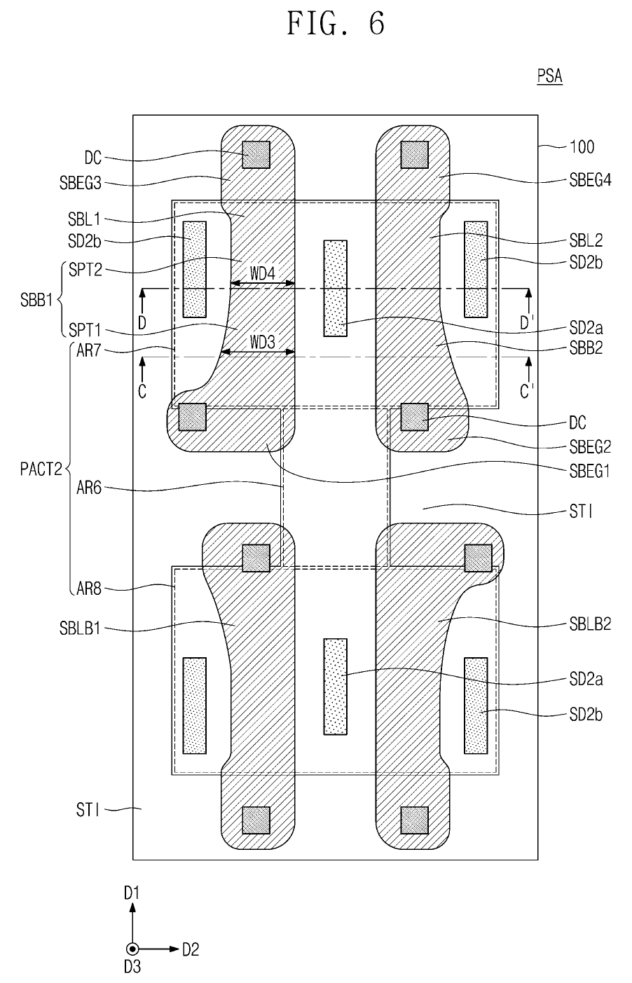

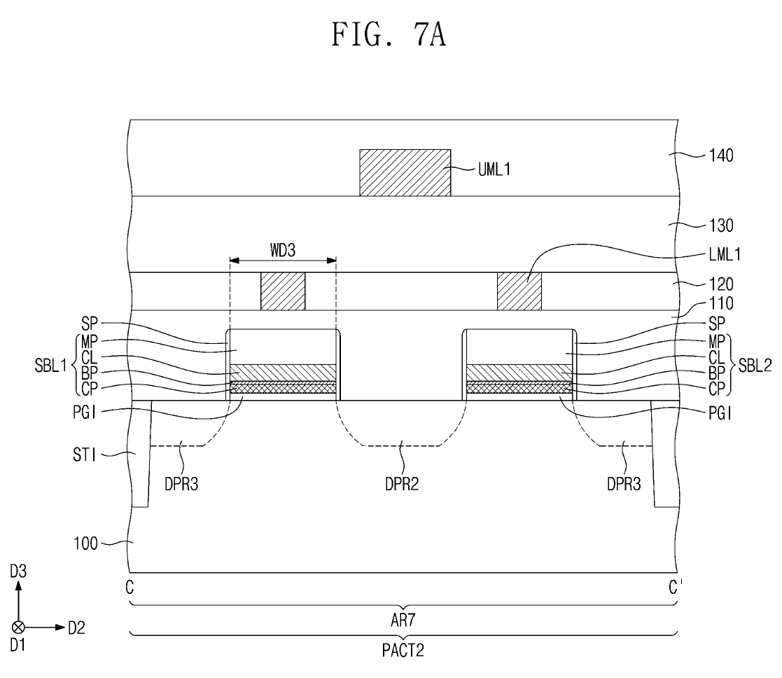

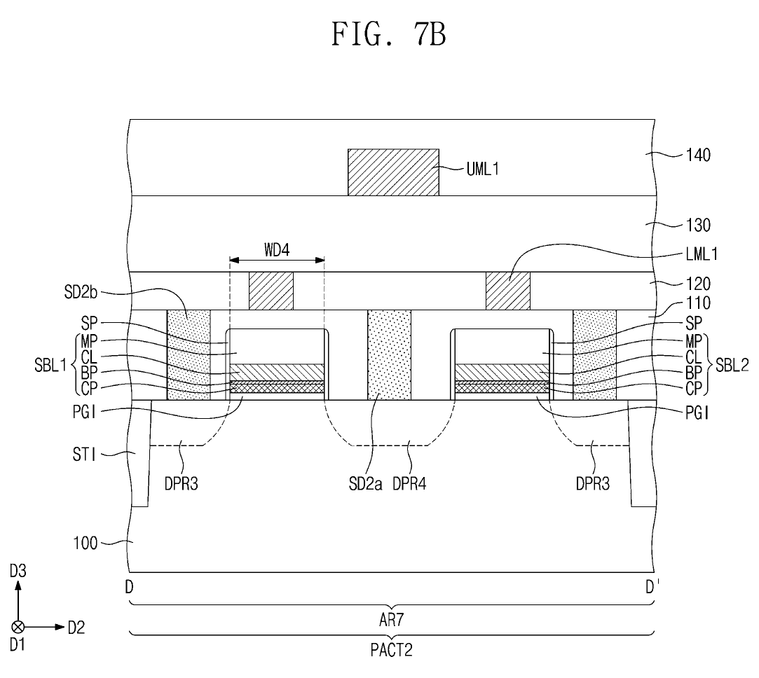

FIG. 6 is an example plan view according to the PMOS region PSA of FIG. 3. FIG. 7A is an example cross-sectional view taken along line C-C’ of FIG. 6. FIG. 7B is an example cross-sectional view taken along line D-D’ of FIG. 6. The PMOS region PSA will be described in more detail with reference to FIGS. 6-7B. Hereinafter, technical features overlapping with the above descriptions provided with reference to FIGS. 4A-5B will be omitted.

Referring to FIGS. 6-7B, a device isolation layer STI defining a second peripheral active region PACT2 may be provided on the substrate 100. In a plan view, the device isolation layer STI may surround the second peripheral active region PACT2.

The second peripheral active region PACT2 may include sixth to eighth regions AR6 to AR8. The seventh region AR7 and the second region AR8 may be spaced apart from each other in the first direction D1. The sixth region AR6 may be provided between and connect the seventh region AR7 and the eighth region AR8. The device isolation layer STI may extend between the seventh region AR7 and the eighth region AR8. A width of the sixth region AR6 may be less than a width of the seventh region AR7 and a width of the eighth region AR8.

The sixth to eighth regions AR6 to AR8 may constitute a PMOS transistor. A second drain pattern SD2b and a second source pattern SD2a may be respectively provided on the seventh region AR7 and the eighth region AR8. The second source pattern SD2a and the second drain pattern SD2b may extend in the first direction D1. The second source pattern SD2a may be disposed between the second drain patterns SD2b.

The second drain patterns SD2b may be connected to a third impurity region DPR3 of each of the seventh region AR7 and the eighth region AR8. The second source pattern SD2a may be connected to a fourth impurity region DPR4 of each of the seventh region AR7 and the eighth region AR8. The third and fourth impurity regions DPR3 and DPR4 may be p-type doped regions. A current path may be formed from the third impurity region DPR3 to the fourth impurity region DPR4. In other words, a channel region may be formed from the third impurity region DPR3 to the fourth impurity region DPR4.

A first sensing bit line SBL1 and a second sensing bit line SBL2 may be provided on the sixth and seventh regions AR6 and AR7. The first and second sensing bit lines SBL1 and SBL2 may extend in the first direction D1 on the sixth and seventh regions AR6 and AR7 and the device isolation layer STI. The first sensing bit line SBL1 and the second sensing bit line SBL2 may be spaced apart from each other in the second direction D2. The second source pattern SD2a may be located between the first sensing bit line SBL1 and the second sensing bit line SBL2. The second source pattern SD2a and the second drain pattern SD2b may be spaced apart from each other in the second direction D2 with the first sensing bit line SBL1 therebetween. The second source pattern SD2a and the second drain pattern SD2b may be spaced apart from each other in the second direction D2 with the second sensing bit line SBL2 therebetween.

The first sensing bit line SBL1 may include a first sensing bit line end portion SBEG1 and a third sensing bit line end portion SBEG3 facing each other in the first direction D1. The first sensing bit line end portion SBEG1 may vertically overlap the sixth region AR6, the seventh region AR7, and the device isolation layer STI, and the third sensing bit line end portion SBEG3 may vertically overlap the seventh region AR7 and the device isolation layer STI. The first sensing bit line SBL1 may include a first sensing body portion SBB1 between the first sensing bit line end portion SBEG1 and the third sensing bit line end portion SBEG3.

The first sensing bit line end portion SBEG1 and the third sensing bit line end portion SBEG3 may extend in a direction away from the second sensing bit line SBL2. The first sensing bit line end portion SBEG1 may further extend than the third sensing bit line end portion SBEG3, but is not limited thereto.

A width of the first sensing bit line end portion SBEG1 and a width of the third sensing bit line end portion SBEG3 may be larger than a width of the first sensing body portion SBB1. The width of the first sensing body portion SBB1 may increase toward the first sensing bit line end portion SBEG1 and the third sensing bit line end portion SBEG3. For example, the first sensing body portion SBB1 may include a first sensing portion SPT1 adjacent to the first sensing bit line end portion SBEG1 and a second sensing portion SPT2 between the second source pattern SD2a and the second drain pattern SD2b. The first sensing portion SPT1 may have a third width WD3 in the second direction D2, and the second sensing portion SPT2 may have a fourth width WD4 in the second direction D2. The third width WD3 may be larger than the fourth width WD4.

The first sensing bit line end portion SBEG1 and the third sensing bit line end portion SBEG3 may each have a sidewall protruding above the first sensing body portion SSB1 in a direction away from the second sensing bit line SBL2. The first sensing body portion SBB1 may have a sidewall having a profile concave inward toward an inner side of the first sensing body portion SBB1.

The second sensing bit line SBL2 may have substantially the same features as the first sensing bit line SBL1. In detail, the second sensing bit line SBL2 may include a second sensing bit line end portion SBEG2 and a fourth sensing bit line end portion SBEG4 facing each other in the first direction D1. The second sensing bit line end portion SBEG2 may correspond to the first sensing bit line end portion SBEG1, and the fourth sensing bit line end portion BEG4 may correspond to the third sensing bit line end portion SBEG3.

The second and fourth sensing bit line end portions SBEG2 and SBEG4 may extend in a direction away from the first sensing bit line SBL1. However, a width of the second sensing bit line end portion SBEG2 in the second direction D2 may be less than a width of the first sensing bit line end portion SBEG1, but is not limited thereto.

The second sensing bit line SBL2 may include a second sensing body portion SBB2 between the second sensing bit line end portion SBEG2 and the fourth sensing bit line end portion SBEG4. The second sensing body portion SBB2 may correspond to the first sensing body portion SBB1.

Lower contacts DC may be respectively formed on the first to fourth sensing bit line end portions SBEG1 to SBEG4. The lower contacts DC may connect the first and second sensing bit lines SBL1 and SBL2 to lower lines LML1 that will be described later.

A first complementary sensing bit line SBLB1 and a second complementary sensing bit line SBLB2 may be provided on the sixth and eighth regions AR6 and AR8. The first complementary sensing bit line SBLB1 may be paired with the first sensing bit line SBL1, and the second complementary sensing bit line SBLB2 may be paired with the second sensing bit line SBL2. The first complementary sensing bit line SBLB1 may include substantially the same technical features as the second sensing bit line SBL2, and the second complementary sensing bit line SBLB2 may include substantially the same technical features as the first sensing bit line SBL1.

The first and second sensing bit lines SBL1 and SBL2 may also include a first conductive pattern CP, a barrier pattern BP, a second conductive pattern CL, and an etching pattern MP that are sequentially stacked, like the first and second bit lines BL1 and BL2. A peripheral gate insulating layer PGI may be provided between the first and second sensing bit lines SBL1 and SBL2 and the substrate 100. In other words, the peripheral gate insulating layer PGI may be interposed between the first conductive pattern CP and the substrate 100. A pair of spacers SP may be provided on both sidewalls of the first and second sensing bit lines SBL1 and SBL2.

The first and second complementary sensing bit lines SBLB1 and SBLB2 may include substantially the same components as the first and second sensing bit lines SBL1 and SBL2. In detail, the first and second complementary sensing bit lines SBLB1 and SBLB2 may also include a first conductive pattern CP, a barrier pattern BP, a second conductive pattern CL, and an etching pattern MP that are sequentially stacked.

A first interlayer insulating layer 110 may be provided on the substrate 100. The first interlayer insulating layer 110 may cover the first and second bit lines BL1 and BL2, the first and second complementary bit lines BLB1 and BLB2, the first and second sensing bit lines SBL1 and SBL2, and the first and second complementary sensing bit lines SBLB1 and SBLB2. The first and second source patterns SD1a and SD2a and the first and second drain patterns SD1b and SD2b may penetrate the first interlayer insulating layer 110.

A second interlayer insulating layer 120, a third interlayer insulating layer 130, and a fourth interlayer insulating layer 140 may be provided on the first interlayer insulating layer 110. Lower lines LML1 may be provided in the second interlayer insulating layer 120, and upper lines UML1 may be provided in the fourth interlayer insulating layer 140. Via lines V1 vertically connecting the lower lines LML1 and the upper lines UML1 may be provided in the third interlayer insulating layer 130.

According to the present disclosure, the first and second sensing bit line end portions SBEG1 and SBEG2 of the first and second sensing bit lines SBL1 and SBL2 may have larger widths than those of the first and second sensing body portions SBB1 and SBB2. Furthermore, the first and second sensing body portions SBB1 and SBB2 may increase in width toward the first to fourth sensing bit line end portions SBEG1 to SBEG4. Therefore, since the widths of the first and second sensing bit lines SBL1 and SBL2 between the second drain pattern SD2b and the second source pattern SD2a increase, a channel length may increase.

Furthermore, the first and second sensing bit lines SBL1 and SBL2 and the first and second complementary sensing bit lines SBLB1 and SBLB2 have the same profiles symmetric with each other, a mismatch between the first sensing bit line SBL1 and the first complementary sensing bit line SBLB1 and between the second sensing bit line SBL2 and the second complementary sensing bit line SBLB2 may be minimized. As a result, reliability and electrical characteristics of the semiconductor memory device of the present disclosure may be improved.

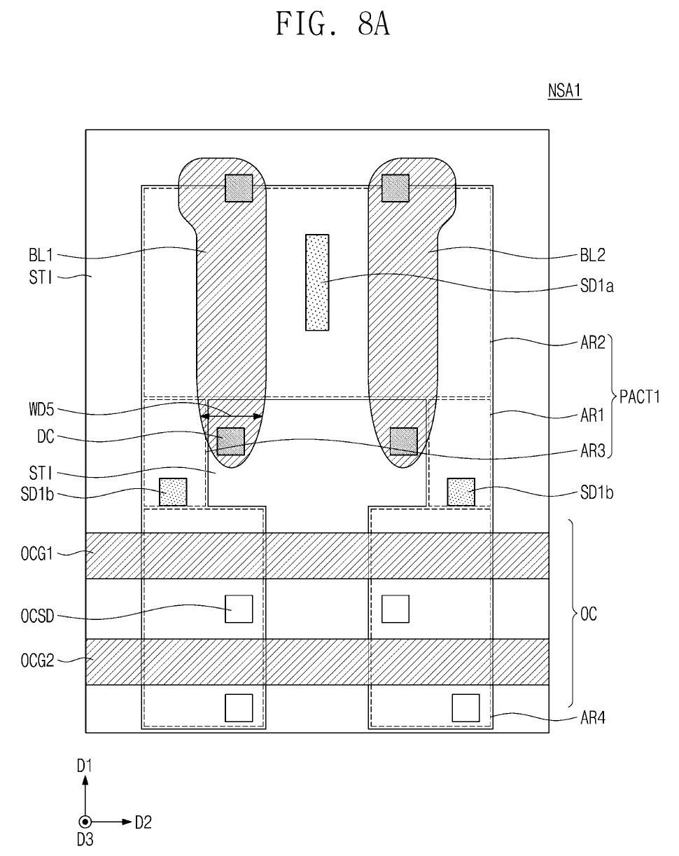

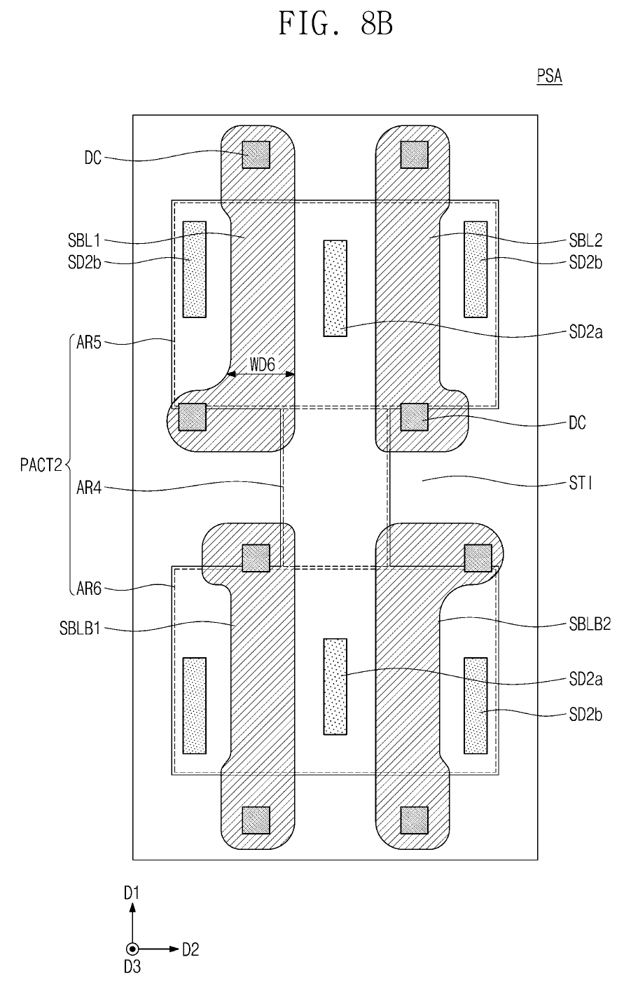

FIG. 8A is an example plan view of the first NMOS region NSA1 of FIG. 3. FIG. 8B is an example plan view of the PMOS regions PSA of FIG. 3. Hereinafter, technical features overlapping with the above descriptions provided with reference to FIGS. 4A-7B will be omitted.

Referring to FIG. 8A, the first bit line end portion BEG1 of the first bit line BL1 may have a fifth width WD5 in the second direction D2. The fifth width WD5 may be less than the first width WD1 and the second width WD2 of FIG. 4A. The first bit line end portion BEG1 may have a smaller width than the first bit line body portion BB1. This is because an area of the first bit line end portion BEG1 of the first bit line BL1 reduces due to a rounding effect of a first patterning process in a manufacturing method that will be described later. Since the width of the first bit line end portion BEG1 decreases, a channel length may decrease, and thus electrical characteristics of a semiconductor memory device may deteriorate.

Furthermore, due to the rounding effect, a mismatch between the first bit line BL1 and the first complementary bit line BLB1 may be maximized. This may be caused by a decrease in the width of each of the first bit line BL1 and the first complementary bit line BLB1.

Referring to FIG. 8B, the first sensing body portion SBB1 of the first sensing bit line SBL1 may have a first body portion adjacent to the first sensing bit line end portion SBEG1, and the first body portion may have a sixth width WD6 in the second direction D2. The sixth width WD6 may be less than the third width WD3 of FIG. 6. In other words, an area of the first sensing bit line SBL1 may be less than that of the first sensing bit line SBL1 of FIG. 6. Therefore, the channel length may decrease, and thus the electrical characteristics of a semiconductor memory device may deteriorate.

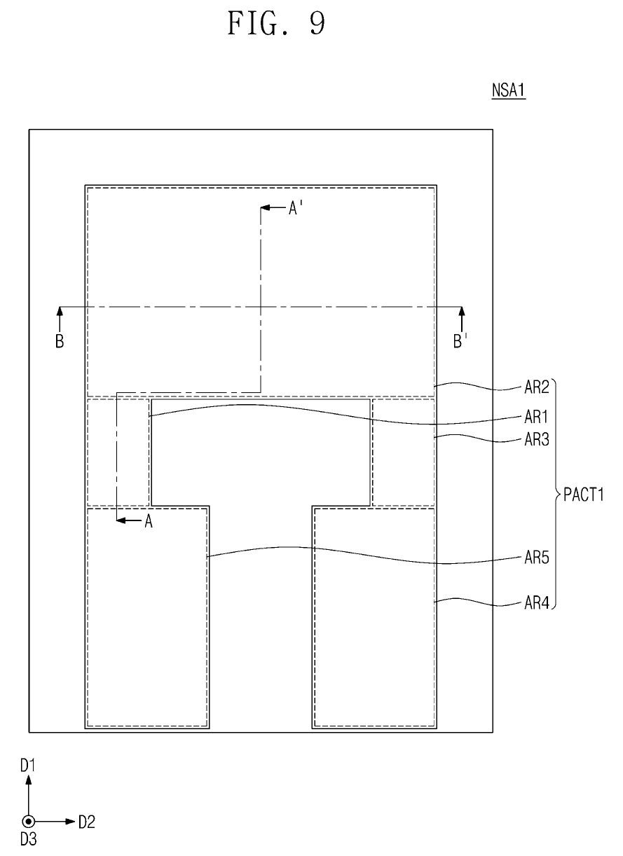

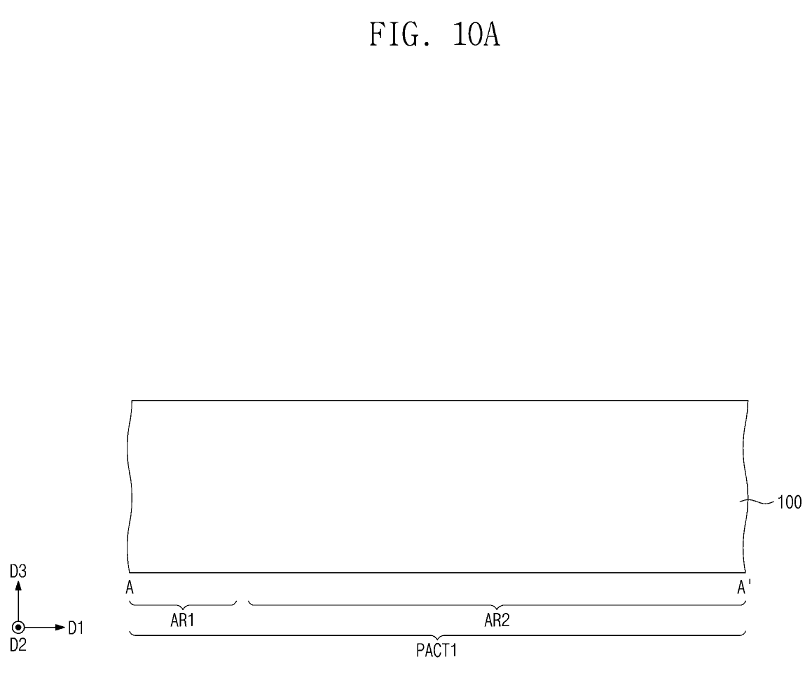

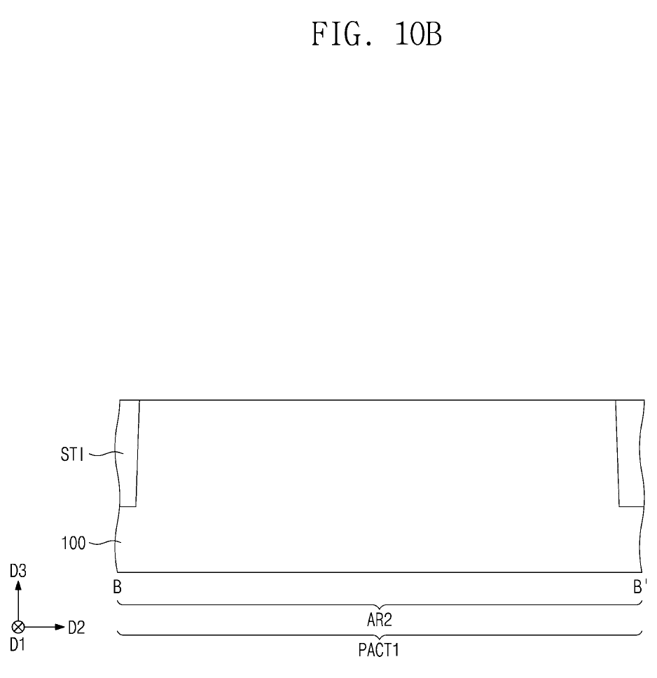

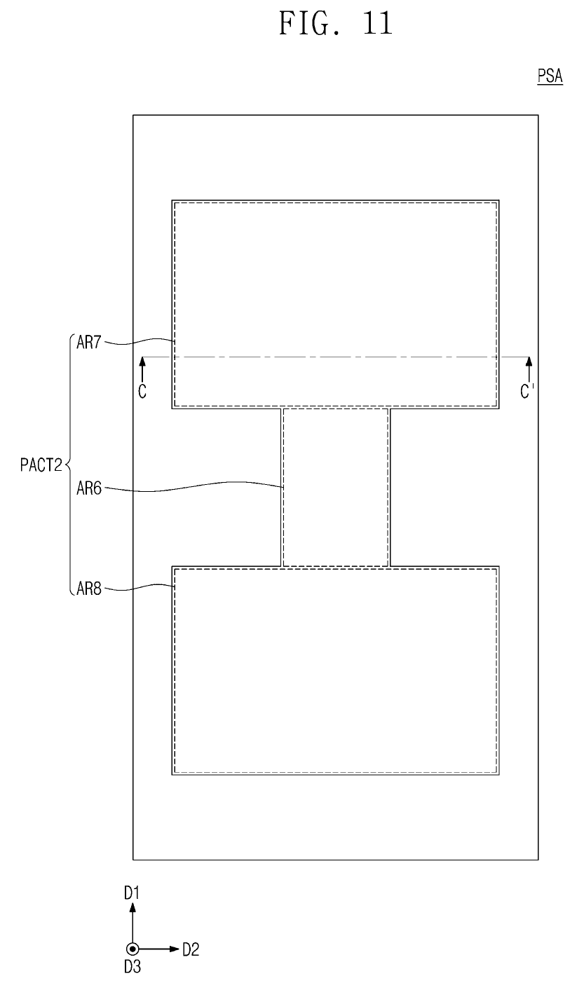

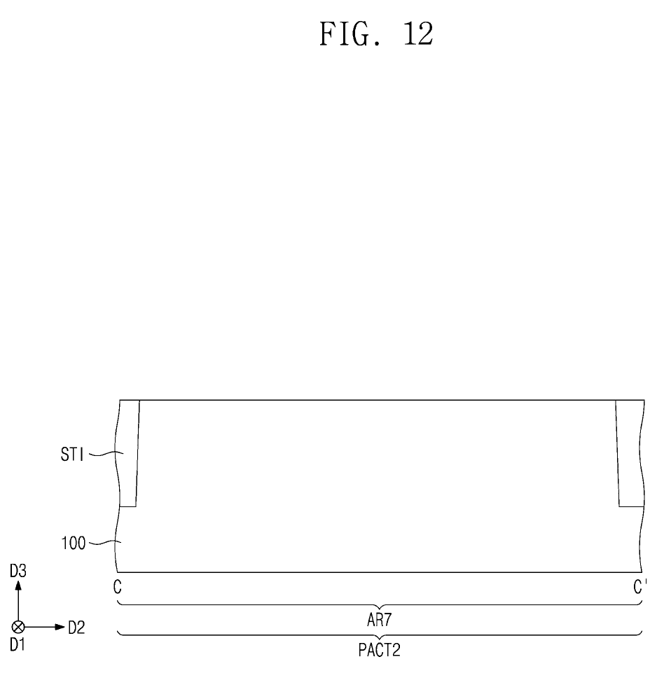

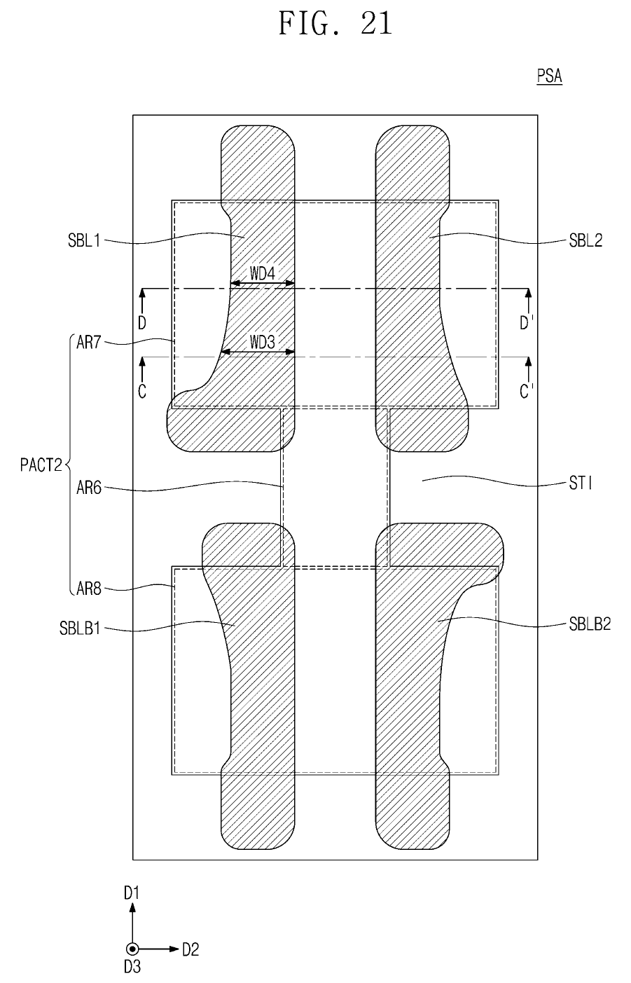

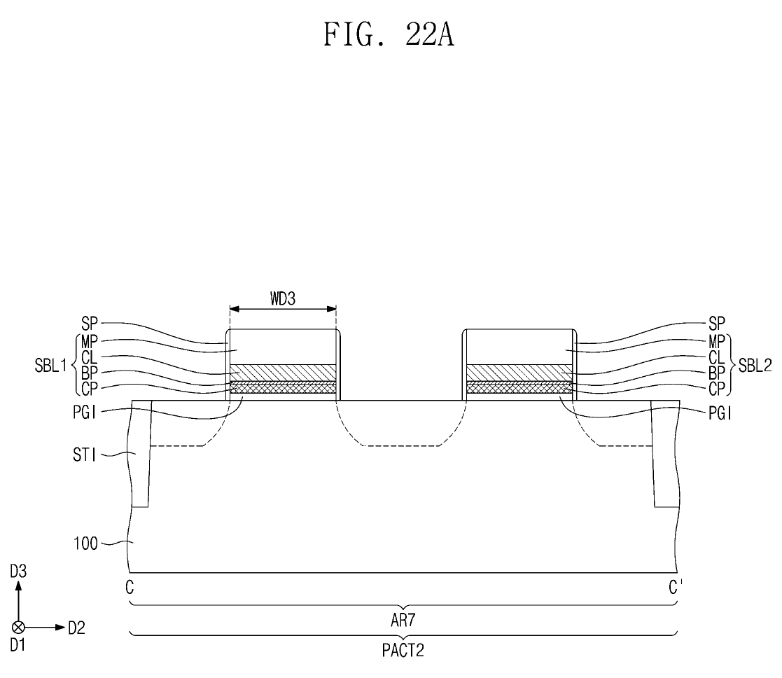

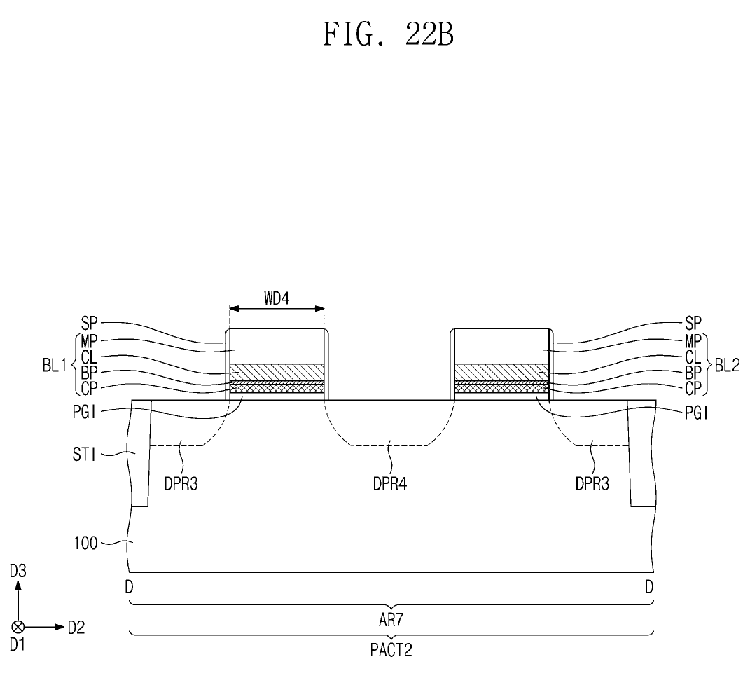

FIGS. 9, 10A, 10B, 11, 12, 13, 14A, 14B, 15, 16, 19, 20A, 20B, 21, 22A and 22B are diagrams for describing an example of a method for manufacturing a semiconductor memory device. In detail, FIGS. 9, 13 and 19 are plan views according to the first NMOS region NSA1 of FIG. 3. FIGS. 11, 15 and 21 are plan views according to the PMOS region PSA of FIG. 3. FIGS. 10A, 14A and 20A are cross-sectional views taken along lines A-A’ of FIGS. 9, 13 and 19, respectively. FIGS. 10B, 14B and 20B are cross-sectional views taken along lines B-B’ of FIGS. 9, 13 and 19, respectively. FIGS. 12, 16 and 22A are cross-sectional views taken along lines C-C’ of FIGS. 11, 15 and 21, respectively. FIG. 22B is a cross-sectional view taken along line D-D’ of FIG. 21.

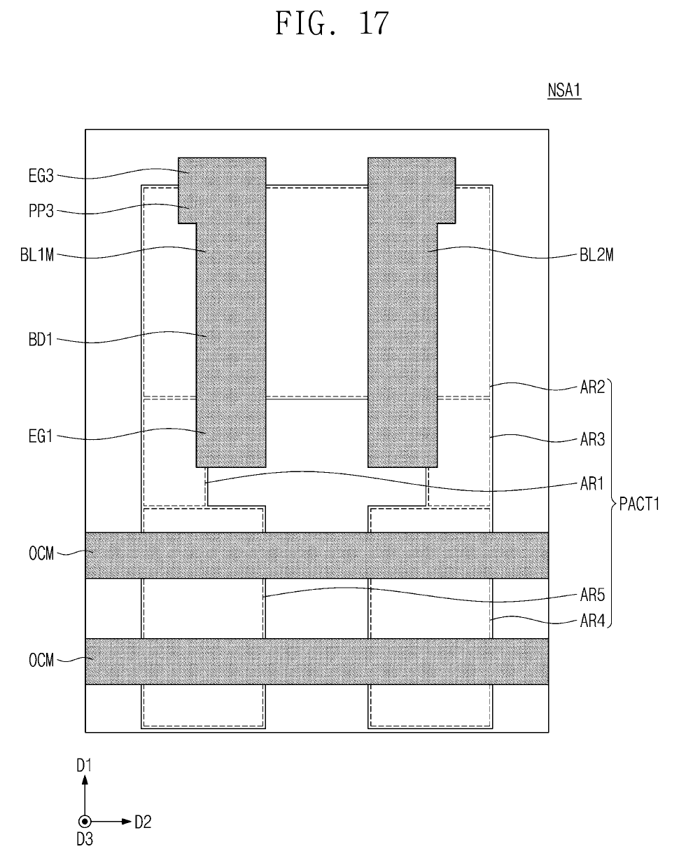

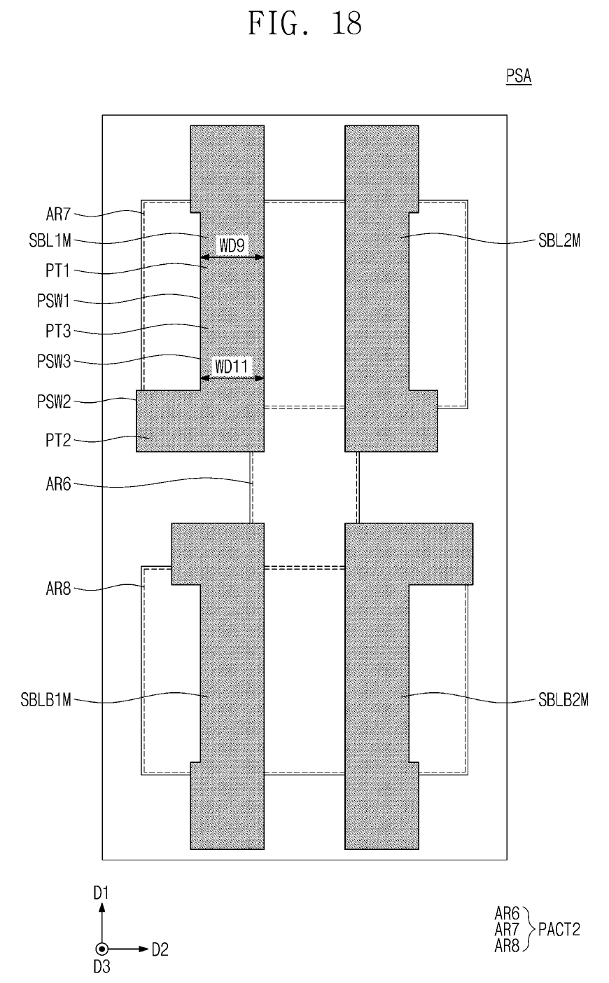

FIG. 17 is a plan view according to the first NMOS region NSA1 of FIG. 3 for describing an example of a method for manufacturing a semiconductor memory device. FIG. 18 is a plan view according to the PMOS region PSA of FIG. 3 for describing an example of a method for manufacturing a semiconductor memory device.

A method for manufacturing a semiconductor memory device will be described with reference to FIGS. 9-22B. Technical features overlapping with the above descriptions provided with reference to FIGS. 3-7B will be omitted. A process that is substantially the same as that of the first NMOS region NSA1 may be performed on the second NMOS region NSA2.

Referring to FIGS. 9-10B, a trench may be formed by performing an etching process on the substrate 100 of the first NMOS region NSA1. The first peripheral active region PACT1 may be formed by the trench. The first peripheral active region PACT1 may include first to fifth regions AR1 to AR5.

The device isolation layer STI may be formed by filling the trench with a silicon oxide layer. The device isolation layer STI may define the first peripheral active region PACT1. An upper surface of the device isolation layer STI may be located at the same level as or lower level than an upper surface of the first peripheral active region PACT1.

Referring to FIGS. 11 and 12, a trench may be formed by performing an etching process on the substrate 100 of the PMOS region PSA. The second peripheral active region PACT2 may be formed by the trench. The second peripheral active region PACT2 may include sixth to eighth regions AR6 to AR8.

The device isolation layer STI may be formed by filling the trench with a silicon oxide layer. The device isolation layer STI may define the second peripheral active region PACT2. An upper surface of the device isolation layer STI may be located at the same level as or lower level than an upper surface of the second peripheral active region PACT2.

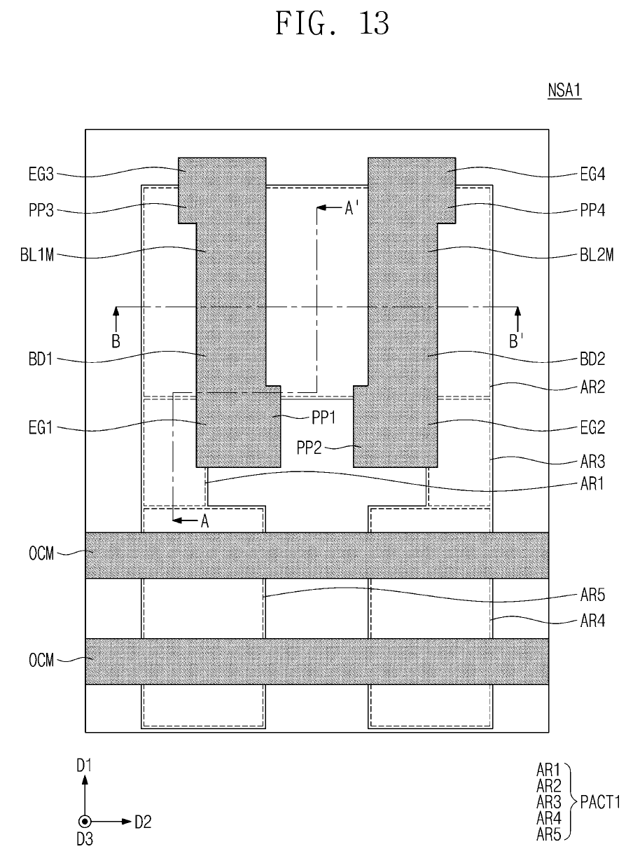

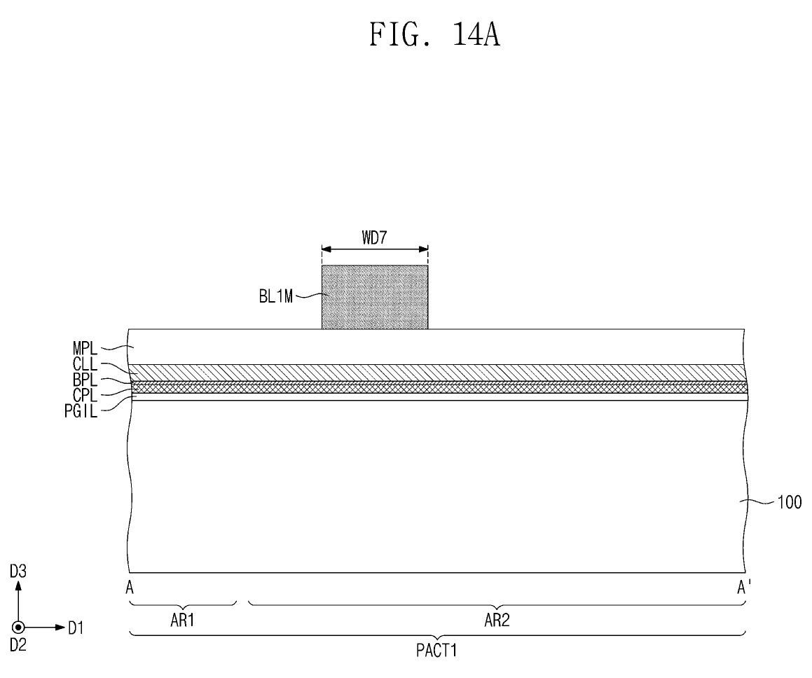

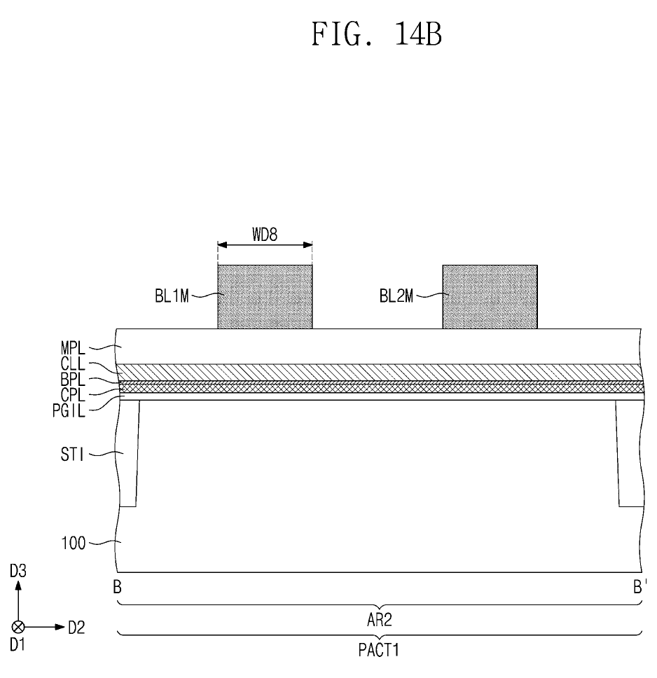

Referring to FIGS. 13-14B, a peripheral gate insulating layer PGIL may be formed on the substrate 100 of the first NMOS region NSA1. Stacked conductive layers CPL, BPL, and BLL may be formed on the peripheral gate insulating layer PGIL. Forming the stacked conductive layers CPL, BPL, and BLL may include sequentially stacking a first conductive pattern layer CPL, a barrier pattern layer BPL, a second conductive pattern layer CLL, and an etching pattern layer MPL.

A first mask pattern may be formed on the etching pattern layer MPL. The first mask pattern may include a first bit line mask pattern BL1M and a second bit line mask pattern BL2M. The first bit line mask pattern BL1M may be a mask corresponding to the first bit line BL1 of FIG. 4A and for forming the first bit line BL1. The second bit line mask pattern BL2M may be a mask corresponding to the second bit line BL2 of FIG. 4A and for forming the second bit line BL2. The first mask pattern may include a material having etch selectivity relative to the etching pattern layer MPL.

The first bit line mask pattern BL1M may include a first end portion EG1 corresponding to the first bit line end portion BEG1 of FIG. 4A. The first bit line mask pattern BL1M may include a first protrusion pattern PP1 protruding from the first end portion EG1 toward the second bit line mask pattern BL2M.

On the contrary, the second bit line mask pattern BL2M may include a second end portion EG2 corresponding to the second bit line end portion BEG2 of FIG. 4A. The second bit line mask pattern BL2M may include a second protrusion pattern PP2 protruding from the second end portion EG2 toward the first bit line mask pattern BL1M. The first bit line mask pattern BL1M and the second bit line mask pattern BL2M may have shapes protruding from the first end portion EG1 and the second end portion EG2 toward each other.

The first bit line mask pattern BL1M may include a third end portion EG3 facing the first end portion EG1 in the first direction D1. The third end portion EG3 may correspond to the third bit line end portion BEG3 of FIG. 4A. The third end portion EG3 may include a third protrusion pattern PP3 protruding in a direction away from the second bit line mask pattern BL2M. Therefore, the first end portion EG1 and the third end portion EG3 of the first bit line mask pattern BL1M may extend in opposite directions.

The first bit line mask pattern BL1M may include a first body portion BD1 between the first end portion EG1 and the third end portion EG3. The first body portion BD1 may extend in the first direction D1 and connect the first end portion EG1 and the third end portion EG3.

The second bit line mask pattern BL2M may include a fourth end portion EG4 facing the second end portion EG2 in the first direction D1. The fourth end portion EG4 may correspond to the fourth bit line end portion BEG4 of FIG. 4A. The fourth end portion EG4 may include a fourth protrusion pattern PP4 protruding in a direction away from the first bit line mask pattern BL1M. Therefore, the second end portion EG2 and the fourth end portion EG4 of the second bit line mask pattern BL2M may extend in opposite directions.

The second bit line mask pattern BL2M may include a second body portion BD2 between the second end portion EG2 and the fourth end portion EG4. The second body portion BD2 may extend in the first direction D1 and connect the second end portion EG2 and the fourth end portion EG4.

The first protrusion pattern PP1 may vertically overlap the device isolation layer STI and the second region AR2. In a plan view, an area in which the first protrusion pattern PP1 and the second region AR2 overlap each other may be less than an area in which the first protrusion pattern PP1 and the device isolation layer STI overlap each other.

Likewise, the second protrusion pattern PP2 may vertically overlap the device isolation layer STI and the second region AR2. In a plan view, an area in which the second protrusion pattern PP2 and the second region AR2 overlap each other may be less than an area in which the second protrusion pattern PP2 and the device isolation layer STI overlap each other.

Due to the first protrusion pattern PP1, a width of the first body portion BD1 of the first bit line mask pattern BL1M in the second direction D2 may be less than a width of the first end portion EG1. For example, a seventh width WD7 of the first end portion EG1 may be lager than an eighth width WD8 of the first body portion BD1. The seventh width WD7 may be equal to or larger than the first width WD1 of FIG. 4A, and the eighth width WD8 may be equal to or larger than the second width WD2 of FIG. 4A.

The first mask pattern may include cancellation mask patterns OCM extending in the second direction D2 on the cancellation region OC. The cancellation mask patterns OCM may correspond to the cancellation gate electrodes OCG1 and OCG2 of FIG. 4A.

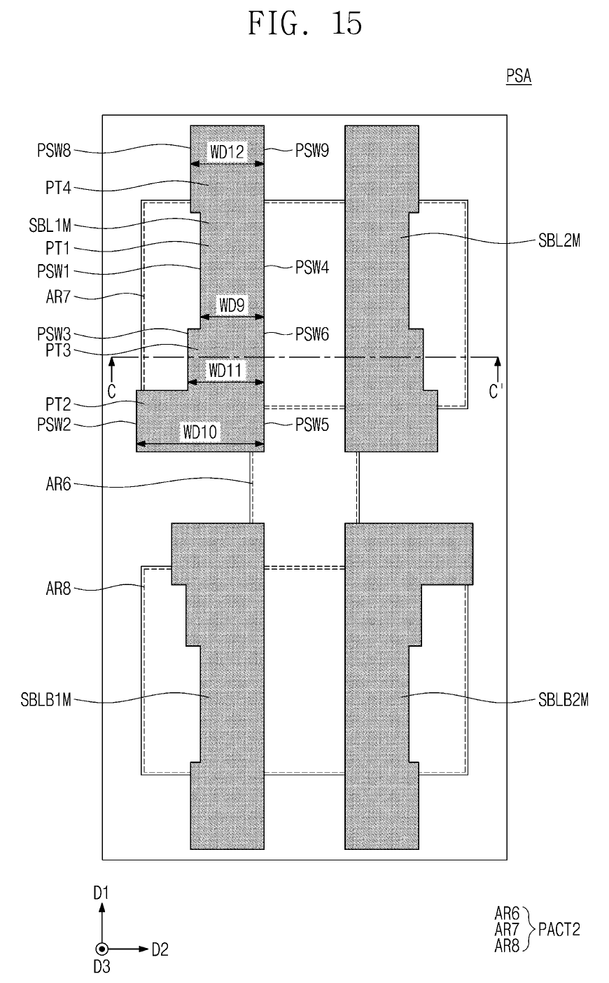

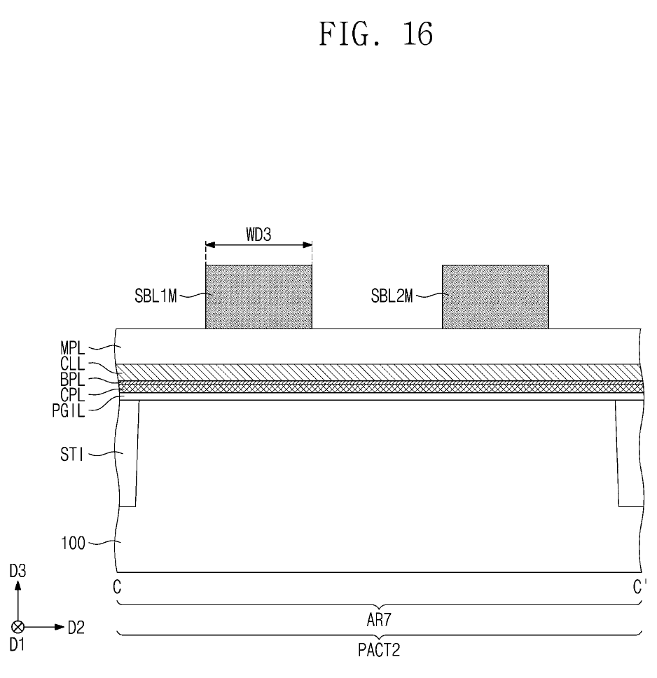

Referring to FIGS. 15 and 16, the peripheral gate insulating layer PGIL may be formed on the substrate 100 of the PMOS region PSA. The stacked conductive layers CPL, BPL, and BLL may be formed on the peripheral gate insulating layer PGIL. Forming the stacked conductive layers CPL, BPL, and BLL may include sequentially forming and stacking a first conductive pattern layer CPL, a barrier pattern layer BPL, a second conductive pattern layer CLL, and an etching pattern layer MPL.

A second mask pattern may be formed on the etching pattern layer MPL. The second mask pattern may include a first sensing bit line mask pattern SBL1M and a second sensing bit line mask pattern SBL2M. The first sensing bit line mask pattern SBL1M may be a mask corresponding to the first sensing bit line SBL1 of FIG. 4A and for forming the first sensing bit line SBL1. The second sensing bit line mask pattern SBL2M may be a mask corresponding to the second sensing bit line SBL2 of FIG. 4A and for forming the second sensing bit line SBL2. The second mask pattern may include a material having etch selectivity relative to the etching pattern layer MPL.

The first sensing bit line mask pattern SBL1M may include a first portion PT1 extending in the first direction D1, a second portion PT2 extending in the second direction D2, and a third portion PT3 between the first portion PT1 and the second portion PT2. The first portion PT1 and the third portion PT3 may correspond to the first sensing body portion SBB1 of FIG. 4A, and the second portion PT2 may correspond to the first sensing bit line end portion SBEG1. The first portion PT1 and the second portion PT2 may be spaced apart from each other in the first direction D1.

A width of the second portion PT2 may be larger than a width of the first portion PT1. A width of the third portion PT3 may be larger than the width of the first portion PT1 and less than the width of the second portion PT2. A step may be formed at a boundary between the first portion PT1 and the third portion PT3, and a step may also be formed at a boundary between the second portion PT2 and the third portion PT3. In a plan view, the first to third portions PT1 to PT3 may have a step profile.

The first portion PT1 may include a first sidewall PSW1, the second portion PT2 may include a second sidewall PSW2, and the third portion PT3 may include a third sidewall PSW3. The first to third sidewalls PSW1 to PSW3 may be located in an opposite direction to the second sensing bit line mask pattern SBL2M.

The third sidewall PSW3 may be spaced apart from the first sidewall PSW1 and the second sidewall PSW2 in the second direction D2. In other words, the third sidewall PSW3 may be offset from the first sidewall PSW1 and the second sidewall PSW2 in the second direction D2. The third sidewall PSW3 may be located spaced apart from the first sidewall PSW1 in a direction away from the second sensing bit line mask pattern SBL2M, and the second sidewall PSW2 may be located spaced apart from the third sidewall PSW3 in a direction away from the second sensing bit line mask pattern SBL2M.

The first portion PT1 may include a fourth sidewall PSW4 facing the first sidewall PSW1 in the second direction D2. The second portion PT2 may include a fifth sidewall PSW5 facing the second sidewall PSW2 in the second direction D2. The third portion PT3 may include a sixth sidewall PSW6 facing the third sidewall PSW3 in the second direction D2. The fourth to sixth sidewalls PSW4 to PSW6 may be adjacent to the second sensing bit line mask patterns SBL2M. The fourth to sixth sidewalls PSW4 to PSW6 may be aligned in the first direction D1. The fourth to sixth sidewalls PSW4 to PSW6 may not be offset from each other, unlike the first to third sidewalls PSW1 to PSW3.

The first sensing bit line mask pattern SBL1M may include a fourth portion PT4 spaced apart from the third portion PT3 with the first portion PT1 therebetween. The fourth portion PT4 may correspond to the second sensing bit line end portion SBEG2 of FIG. 6. A width WD12 of the fourth portion PT4 may be larger than a width WD9 of the first portion PT1. Therefore, a step may be formed at a boundary between the first portion PT1 and the fourth portion PT4.

The fourth portion PT4 may include an eighth sidewall PSW8. The eighth sidewall PSW8 may be located in an opposite direction to the second sensing bit line mask pattern SBL2M. The eighth sidewall PSW8 may be spaced apart from the first sidewall PSW1 in the second direction D2. In other words, the eighth sidewall PSW8 may be offset from the first sidewall PSW1 in the second direction D2. The eighth sidewall PSW8 may be spaced apart from the first sidewall PSW1 in a direction away from the second sensing bit line mask pattern SBL2M.

The fourth portion PT4 may include a ninth sidewall PSW9 facing the eighth sidewall PSW8 in the second direction D2. The ninth sidewall PSW9 may be adjacent to the second sensing bit line mask pattern SBL2M. The ninth sidewall PSW9 may be aligned with the fourth sidewall PSW4 in the first direction D1. The ninth sidewall PSW9 may not be offset from the fourth sidewall PSW4.

The second sensing bit line mask pattern SBL2M may include substantially the same structural feature as the first sensing bit line mask pattern SBL1M. However, the third portion PT3 of the second sensing bit line mask pattern SBL2M may have a smaller width than that of the third portion PT3 of the first sensing bit line mask pattern SBL1M, but is not limited thereto.

The second mask pattern may include first and second complementary sensing bit line mask patterns SBLB1M and SBLB2M on the sixth and eighth regions AR6 and AR8. The first complementary sensing bit line mask pattern SBLB1M may be substantially the same as the second sensing bit line mask pattern SBL2M, and the second complementary sensing bit line mask pattern SBLB2M may be substantially the same as the first sensing bit line mask pattern SBL1M.

Referring to FIG. 17, the first and second bit line mask patterns BL1M and BL2M may not include the first and second protrusion patterns PP1 and PP2, respectively, unlike the present disclosure. Therefore, the width of the first body portion BD1 and the width of the first end portion EG1 may be the same, and the width of the second body portion BD2 and the width of the second end portion EG2 may be the same.

Referring to FIGS. 17 and 8A, the first and second bit lines BL1 and BL2 of FIG. 8A may be formed by performing a first patterning process using the first mask pattern of FIG. 17 as a mask. Since the widths of the first and second end portions EG1 and EG2 decrease, the widths of the first and second bit line end portions BEG1 and BEG2 may also decrease. Therefore, the channel length may decrease, and thus the electrical characteristics of a semiconductor memory device may deteriorate, as described above with reference to FIG. 8A.

Referring to FIG. 18, the third portion PT3 of each of the first and second sensing bit line mask patterns SBL1M and SBL2M may not form a step with the first portion PT1, unlike the present disclosure. Therefore, the width of the first portion PT1 and the width of the third portion PT3 may be the same.

Referring to FIGS. 18 and 8B, the first and second sensing bit lines SBL1 and SBL2 of FIG. 8B may be formed by performing a second patterning process using the second mask pattern of FIG. 18 as a mask. Since a step is not formed between the third portion PT3 and the first portion PT1, the width of the first sensing bit line SBL1 may decrease as described above with reference to FIG. 8B. Therefore, the channel length may decrease, and thus the electrical characteristics of a semiconductor memory device may deteriorate.

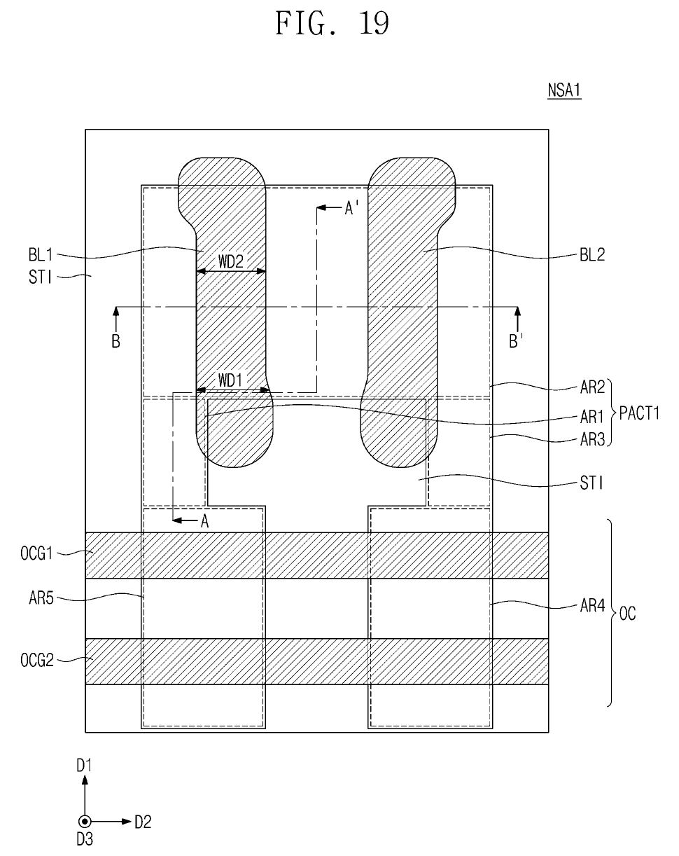

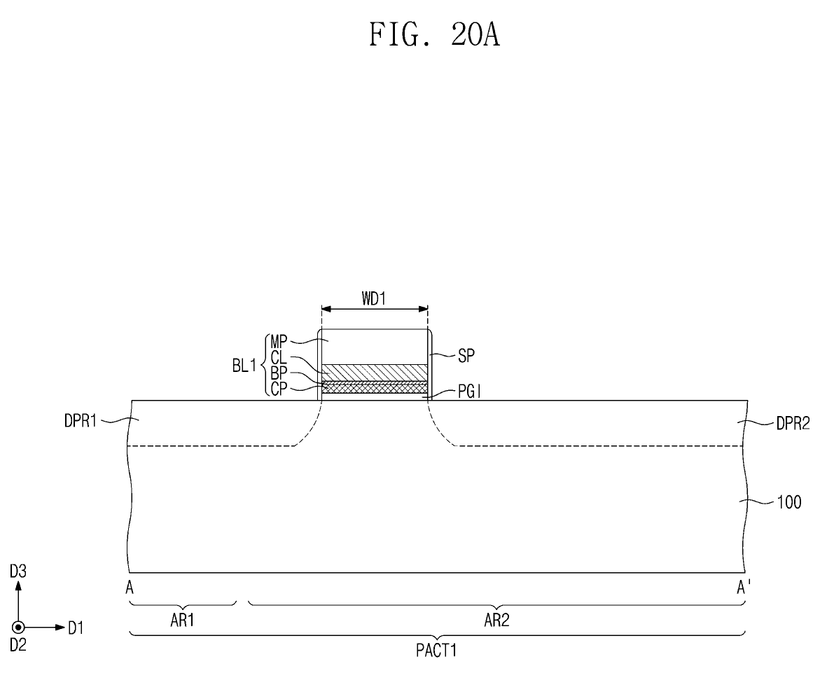

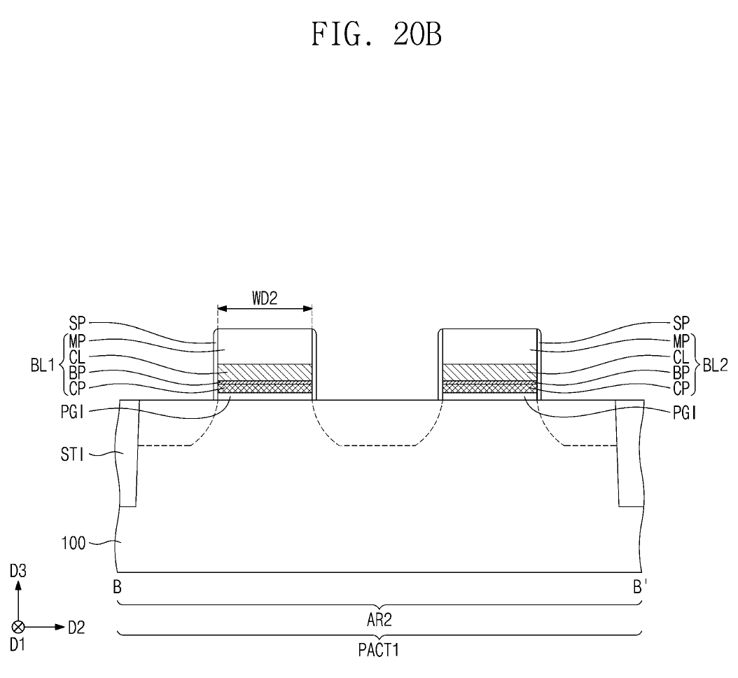

Referring to FIGS. 19-20B, a first patterning process may be performed using a first mask pattern as an etching mask. Due to the first patterning process, the peripheral gate insulating layer PGIL and the stacked conductive layers CPL, BPL, and BLL are patterned so that the first and second bit lines BL1 and BL2 may be formed. A pair of spacers SP may be formed on both sidewalls of the first and second bit lines BL1 and BL2. Through the first patterning process, the cancellation gate electrodes OCG1 and OCG2 of the cancellation region OC may also be formed.

First and second impurity regions DPR1 and DPR2 may be formed by performing an ion injection process on the substrate 100. The first and second impurity regions DPR1 and DPR2 may be doped with n-type.

Referring to FIGS. 21-22B, a second patterning process may be performed using a second mask pattern as an etching mask. Due to the second patterning process, the peripheral gate insulating layer PGIL and the stacked conductive layers CPL, BPL, and BLL are patterned so that the first and second sensing bit lines SBL1 and SBL2 may be formed. A pair of spacers SP may be formed on both sidewalls of the first and second sensing bit lines SBL1 and SBL2.

The third and fourth impurity regions DPR3 and DPR4 may be formed by performing an ion injection process on the substrate 100. The third and fourth impurity regions DPR3 and DPR4 may be doped with p-type.

Forming the second NMOS region NSA2 may include forming a first mask pattern on the substrate 100. Forming the first mask pattern on the second NMOS region NSA2 may be substantially the same as forming the first mask pattern on the substrate 100 of the first NMOS region NSA1. Forming the first complementary bit line BLB1 on the second NMOS region NSA2 may be substantially the same as forming the first bit line BL1, and forming the second complementary bit line BLB2 may be substantially the same as forming the second bit line BL2. However, the first bit line BL1 may be symmetric with the first complementary bit line BLB1 in the first direction D1, and the second bit line BL2 may be symmetric with the second complementary bit line BLB2 in the first direction D1.

Referring back to FIGS. 4A-7B, the first interlayer insulating layer 110 covering the first and second bit lines BL1 and BL2, the first and second complementary bit lines BLB1 and BLB2, the first and second sensing bit lines SBL1 and SBL2, and the first and second complementary sensing bit lines SBLB1 and SBLB2 may be formed on the substrate 100. The first and second source patterns SD1a and SD2a and the first and second drain patterns SD1b and SD2b penetrating the first interlayer insulating layer 110 may be formed.

The first source pattern SD1a may be connected to the second impurity region DPR2, and the first drain pattern SD1b may be connected to the first impurity region. The second source pattern SD2a may be connected to the fourth impurity region DPR4, and the second drain pattern SD2b may be connected to the third impurity region DPR3.

The first source pattern SD1a may be formed between the first bit line BL1 and the second bit line BL2. The first drain pattern SD1b may be formed between the first bit line BL1 and the first cancellation gate electrode OCG1 and between the second bit line BL2 and the first cancellation gate electrode OCG1.

The second source pattern SD2a may be formed between the first sensing bit line SBL1 and the second sensing bit line SBL2. The second drain pattern SD2b may be formed spaced apart from the second source pattern SD2a with the first sensing bit line SBL1 therebetween and spaced apart from the second source pattern SD2a with the second sensing bit line SBL2 therebetween.

The cancellation source pattern OCSD may be formed by performing an ion injection process on the substrate 100 of the cancellation region. The cancellation source pattern OCSD may be formed between the first cancellation gate electrode OCG1 and the second cancellation gate electrode OCG2, but is not limited thereto.

The second interlayer insulating layer 120, the third interlayer insulating layer 130, and the fourth interlayer insulating layer 140 may be sequentially formed on the first interlayer insulating layer 110. For another example, additional interlayer insulating layers may be formed on the fourth interlayer insulating layer 140.

Lower lines LML1 may be formed in the second interlayer insulating layer 120. Forming the lower lines LM1 may include patterning the second interlayer insulating layer 120 and inserting a metal material into the patterned second interlayer insulating layer 120.

Via lines V1 may be formed in the third interlayer insulating layer 130. Forming the via lines V1 may include patterning the third interlayer insulating layer 130 and inserting a metal material into the patterned third interlayer insulating layer 130.

Upper lines UML1 may be formed in the fourth interlayer insulating layer 140. Forming the upper lines UML1 may include patterning the fourth interlayer insulating layer 140 and inserting a metal material into the patterned fourth interlayer insulating layer 140. The upper lines UML1 may be connected by the via lines V1 to the lower lines LML1.

According to a method for manufacturing a semiconductor memory device according to the present disclosure, bit lines may be formed by performing a patterning process using a mask pattern including a protrusion pattern in a bit line sense amplifier region. A first mask pattern on an NMOS region may include a protrusion pattern protruding toward a source pattern, and a second mask pattern on a PMOS region may include a protrusion pattern protruding toward a drain pattern. Therefore, a mismatch between a bit line and a complementary bit line may be minimized by minimizing the rounding effect of a patterning process. Furthermore, the channel length may be increased by increasing the area of bit lines. As a result, a semiconductor memory device according to a manufacturing method of the present disclosure may have improved reliability and electrical characteristics since a process defect reduces.

A semiconductor memory device according to the present disclosure may include a substrate including a PMOS region and a first NMOS region and a second NMOS region that are spaced apart from each other in a first direction with the PMOS region therebetween; a first bit line and a second bit line extending in the first direction on the first NMOS region, wherein the first bit line and the second bit line are spaced apart from each other in a second direction intersecting the first direction; and a first source pattern between the first bit line and the second bit line, wherein the first bit line may have a first bit line body portion and a first bit line end portion connected to the bit line body portion in the first direction, the second bit line may have a second bit line body portion and a second bit line end portion connected to the second bit line body portion in the first direction, the first bit line end portion may extend toward the second bit line in the second direction, and the second bit line end portion may extend toward the first bit line in the second direction.

A semiconductor memory device according to the present disclosure may include a substrate including a PMOS region and a first NMOS region and a second NMOS region that are spaced apart from each other in a first direction with the PMOS region therebetween; a first sensing bit line and a second sensing bit line extending in the first direction on the PMOS region, wherein the first sensing bit line and the second sensing bit line are spaced apart from each other in a second direction intersecting the first direction; a drain pattern spaced apart from the second sensing bit line in the second direction with the first sensing bit line therebetween; and a source pattern between the first sensing bit line and the second sensing bit line, wherein the first sensing bit line may include: a first sensing bit line body portion extending in the first direction; and a first sensing bit line end portion extending in the second direction, wherein the first sensing bit line body portion may include a first sensing portion adjacent to the first sensing bit line end portion and a second sensing portion between the drain pattern and the source pattern, a length of the first sensing portion in the second direction may be larger than a length of the second sensing portion in the second direction, and a length of the first sensing bit line end portion in the second direction may be larger than the length of the first sensing portion.

A semiconductor memory device according to the present disclosure may include a substrate; a PMOS region on the substrate and a first NMOS region and a second NMOS region that are spaced apart from each other in a first direction with the PMOS region therebetween, wherein the first NMOS region includes a cancellation region adjacent to the PMOS region; a first bit line and a second bit line extending in the first direction on the first NMOS region, wherein the first bit line and the second bit line are spaced apart from each other in a second direction intersecting the first direction; a first source pattern between the first bit line and the second bit line; a cancellation gate electrode extending in the second direction on the cancellation region; a first interlayer insulating layer on the first bit line and the second bit line; first drain patterns provided between the first bit line and the cancellation gate electrode and between the second bit line and the cancellation gate electrode; and a wiring layer on the first interlayer insulating layer, wherein the first bit line may have a first bit line body portion and a first bit line end portion, the second bit line may have a second bit line body portion and a second bit line end portion, the first bit line end portion may extend toward the second bit line in the second direction, and the second bit line end portion may extend toward the first bit line in the second direction.

According to the present disclosure, bit lines may be formed by performing a patterning process using a mask pattern including a protrusion pattern in a bit line sense amplifier region. A first mask pattern on an NMOS region may include a protrusion pattern protruding toward a source pattern, and a second mask pattern on a PMOS region may include a protrusion pattern protruding toward a drain pattern. Therefore, a mismatch between a bit line and a complementary bit line may be minimized by minimizing the rounding effect of a patterning process. Furthermore, the channel length may be increased by increasing the area of bit lines. As a result, a semiconductor memory device according to a manufacturing method of the present disclosure may have improved reliability and electrical characteristics since a process defect reduces.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although implementations of the present disclosure have been described with reference to the accompanying drawings, those of ordinary skill in the art could easily understood that the present disclosure can be carried out in other specific forms without changing the technical concept or essential features. Therefore, the above implementations should be considered illustrative and should not be construed as limiting.

What is claimed is:

1. A method for manufacturing a semiconductor memory device, the method comprising forming a PMOS region, a first NMOS region, and a second NMOS region on a substrate, wherein the first NMOS region and the second NMOS region are spaced apart from each other in a first direction, and the PMOS region is between the first NMOS region and the second NMOS region,
wherein forming the first NMOS region includes:
performing a first patterning process to form a first bit line and a second bit line using a first mask pattern, wherein the first bit line and the second bit line extend in the first direction on the substrate and are spaced apart from each other in a second direction intersecting the first direction; and
forming a first source pattern between the first bit line and the second bit line,
wherein the first mask pattern includes a first bit line mask pattern corresponding to the first bit line and a second bit line mask pattern corresponding to the second bit line,
wherein the first bit line mask pattern includes a first protrusion pattern protruding from a first end portion of the first bit line mask pattern toward the second bit line mask pattern, and
wherein the second bit line mask pattern includes a second protrusion pattern protruding from a second end portion of the second bit line mask pattern toward the first bit line mask pattern.

2. The method of claim 1,
wherein the first bit line mask pattern includes a third end portion facing the first end portion in the first direction, and
wherein the third end portion includes a third protrusion pattern protruding in a direction away from the second bit line mask pattern.

3. The method of claim 1,
wherein the second bit line mask pattern includes a fourth end portion facing the second end portion in the first direction, and
wherein the fourth end portion includes a fourth protrusion pattern protruding in a direction away from the first bit line mask pattern.

4. The method of claim 1,
wherein forming the first NMOS region includes forming a peripheral active region and a device isolation layer on the substrate, the device isolation layer defining the peripheral active region, and
wherein the first protrusion pattern and the second protrusion pattern have a first area overlapping the peripheral active region and a second area overlapping the device isolation layer, and the first area is smaller than the second area.

5. The method of claim 1,
wherein the first NMOS region includes a cancellation region adjacent to the PMOS region,
wherein the cancellation region includes a cancellation gate electrode extending in the second direction, and
wherein forming the first NMOS region includes forming first drain patterns between the first bit line and the cancellation gate electrode and between the second bit line and the cancellation gate electrode.

6. The method of claim 1,
wherein forming the second NMOS region includes:
forming a first complementary bit line corresponding to the first bit line; and
forming a second complementary bit line corresponding to the second bit line,
wherein the first bit line and the first complementary bit line are symmetric with each other in the first direction, and
wherein the second bit line and the second complementary bit line are symmetric with each other in the first direction.

7. The method of claim 1,
wherein forming the PMOS region includes:
performing a second patterning process to form, on the substrate, a first sensing bit line and a second sensing bit line using a second mask pattern, wherein the first sensing bit line and the second sensing bit line extend in the first direction and are spaced apart from each other in the second direction;
forming a second drain pattern spaced apart from the second sensing bit line in the second direction, the first sensing bit line being between the second drain pattern and the second sensing bit line; and
forming a third drain pattern spaced apart from the first sensing bit line in the second direction, the second sensing bit line being between the third drain pattern and the first sensing bit line,
wherein the second mask pattern includes a first sensing bit line mask pattern corresponding to the first sensing bit line and a second sensing bit line mask pattern corresponding to the second sensing bit line.

8. The method of claim 7,
wherein each of the first sensing bit line mask pattern and the second sensing bit line mask pattern includes:
a first portion extending in the first direction;
a second portion extending in the second direction and spaced apart from the first portion in the first direction; and
a third portion between the first portion and the second portion,
wherein a width of the third portion is larger than a width of the first portion and is less than a width of the second portion.

9. The method of claim 8,
wherein each of the first portion, the second portion, and the third portion includes a first sidewall, a second sidewall, and a third sidewall, and
wherein the third sidewall is offset from the first sidewall and the second sidewall.

10. The method of claim 9,
wherein each of the first portion, the second portion, and the third portion includes a fourth sidewall, a fifth sidewall, and a sixth sidewall facing the first sidewall, the second sidewall, and the third sidewall in the second direction, respectively, and
wherein the fourth sidewall, the fifth sidewall, and the sixth sidewall are aligned in the first direction.

11. A method for manufacturing a semiconductor memory device, the method comprising forming, on a substrate, a PMOS region, a first NMOS region, and a second NMOS region that are spaced apart from each other in a first direction, the PMOS region being between the first NMOS region and the second NMOS region,
wherein forming the PMOS region includes:
performing a first patterning process to form, on the substrate, a first sensing bit line and a second sensing bit line using a first mask pattern, wherein the first sensing bit line and the second sensing bit line extend in the first direction and are spaced apart from each other in a second direction intersecting the first direction; and
forming a drain pattern spaced apart from the second sensing bit line in the second direction, the first sensing bit line being between the drain pattern and the second sensing bit line,
wherein the first mask pattern includes a first sensing bit line mask pattern corresponding to the first sensing bit line, and
wherein the first sensing bit line mask pattern includes:
a first portion extending in the first direction;
a second portion extending in the second direction and spaced apart from the first portion in the first direction; and
a third portion between the first portion and the second portion,
wherein each of the first portion, the second portion, and the third portion includes a first sidewall, a second sidewall, and a third sidewall, and
wherein the third sidewall is offset from the first sidewall and the second sidewall in the second direction.

12. The method of claim 11, wherein a width of the third portion is larger than a width of the first portion and is less than a width of the second portion.

13. The method of claim 11,
wherein forming the first NMOS region includes:
performing a second patterning process to form a first bit line and a second bit line using a second mask pattern, wherein the first bit line and the second bit line extend in the first direction on the substrate and are spaced apart from each other in the second direction intersecting the first direction; and
forming a first source pattern between the first bit line and the second bit line,
wherein the first mask pattern includes a first bit line mask pattern corresponding to the first bit line and a second bit line mask pattern corresponding to the second bit line,
wherein the first bit line mask pattern includes a first protrusion pattern protruding from a first end portion of the first bit line mask pattern toward the second bit line mask pattern, and
wherein the second bit line mask pattern includes a second protrusion pattern protruding from a second end portion of the second bit line mask pattern toward the first bit line mask pattern.

14. The method of claim 13,
wherein the first bit line mask pattern includes a third end portion facing the first end portion in the first direction, and
wherein the third end portion includes a third protrusion pattern protruding in a direction away from the second bit line mask pattern.

15. The method of claim 13,
wherein the second bit line mask pattern includes a fourth end portion facing the second end portion in the first direction, and
wherein the fourth end portion includes a fourth protrusion pattern protruding in a direction away from the first bit line mask pattern.

16. A method for manufacturing a semiconductor memory device, the method comprising forming a PMOS region, a first NMOS region, and a second NMOS region, wherein the first NMOS region and the second NMOS region are spaced apart from each other in a first direction, and the PMOS region is between the first NMOS region and the second NMOS region,
wherein the forming of the first NMOS region includes:
performing a first patterning process to form a first bit line and a second bit line using a first mask pattern, wherein the first bit line and the second bit line extend in the first direction on a substrate and are spaced apart from each other in a second direction intersecting the first direction;
forming a cancellation region adjacent to the PMOS region, wherein the cancellation region includes a cancellation gate electrode extending in the second direction;
forming a first interlayer insulating layer on the first and second bit lines;
forming a first source pattern between the first bit line and the second bit line;
forming first drain patterns between the first bit line and the cancellation gate electrode and between the second bit line and the cancellation gate electrode; and
forming a wiring layer on the first interlayer insulating layer,
wherein the first mask pattern includes a first bit line mask pattern corresponding to the first bit line and a second bit line mask pattern corresponding to the second bit line,
wherein the first bit line mask pattern includes a first protrusion pattern protruding from a first end portion of the first bit line mask pattern toward the second bit line mask pattern, and
wherein the second bit line mask pattern includes a second protrusion pattern protruding from a second end portion of the second bit line mask pattern toward the first bit line mask pattern.

17. The method of claim 16,
wherein forming the first NMOS region includes forming, on the substrate, a peripheral active region and a device isolation layer, the device isolation layer defining the peripheral active region, and
wherein the first protrusion pattern and the second protrusion pattern have a first area overlapping the peripheral active region and a second area overlapping the device isolation layer, and the first area is smaller than the second area.

18. The method of claim 16,
wherein forming the PMOS region includes:
performing a second patterning process to form, on the substrate, a first sensing bit line and a second sensing bit line using a second mask pattern, wherein the first sensing bit line and the second sensing bit line extend in the first direction and are spaced apart from each other in the second direction; and
forming a second drain pattern spaced apart from the second sensing bit line in the second direction, the first sensing bit line being between the second drain pattern and the second sensing bit line,
wherein the second mask pattern includes a first sensing bit line mask pattern corresponding to the first sensing bit line, and
wherein the first sensing bit line mask pattern includes:
a first portion extending in the first direction;
a second portion extending in the second direction and spaced apart from the first portion in the first direction; and
a third portion between the first portion and the second portion,
wherein a width of the third portion is larger than a width of the first portion and is less than a width of the second portion.

19. The method of claim 16,
wherein the first bit line mask pattern includes a third end portion facing the first end portion in the first direction, and
wherein the third end portion includes a third protrusion pattern protruding in a direction away from the second bit line mask pattern.

20. The method of claim 16,
wherein forming the second NMOS region includes:
forming a first complementary bit line corresponding to the first bit line; and
forming a second complementary bit line corresponding to the second bit line,
wherein the first bit line and the first complementary bit line are symmetric with each other in the first direction, and
wherein the second bit line and the second complementary bit line are symmetric with each other in the first direction.
